(19) United States
(12) Patent Application Publication
(10) Pub. No.: US 2015/0349214 A1
(43) Pub. Date: Dec. 3, 2015

(54) Optoelectronic Semiconductor Chip

(71) Applicant: OSRAM OPTO SEMICONDUCTORS, Regensburg (DE)

(72) Inventors: Tobias MEYER, Ihrlerstein (DE); Matthias PETER, Regensburg (DE); Michaela WEBER, Pentling (DE); Tobias GOTSCHKE, Nittendorf (DE); Jürgen OFF, Regensburg (DE)

(21) Appl. No.: 14/759,077

(22) PCT Filed: Jan. 8, 2014
(86) PCT No.: PCT/EP2014/050238

§ 371 Date: Jul. 2, 2015

(30) Foreign Application Priority Data
Jan. 15, 2013 (DE) 10 2013 200 509.1

(51) Int. Cl. H01L 33/50; H01L 33/22; H01L 33/30

(52) U.S. Cl. CPC H01L 33/502; H01L 33/30; H01L 33/22

(57) ABSTRACT

An optoelectronic semiconductor chip, comprising: a semiconductor layer sequence having an active zone for generating a light radiation; and a conversion structure, comprising conversion regions for converting the generated light radiation, non-converting regions being arranged between said conversion regions.

The invention relates to an optoelectronic semiconductor chip, comprising a semiconductor layer sequence having an active zone for generating a light radiation. The invention furthermore relates to a method for producing an optoelectronic semiconductor chip.

Optoelectronic semiconductor chips such as, in particular, LED chips (Light Emitting Diode) usually comprise a substrate and a semiconductor layer sequence arranged on the substrate. The semiconductor layer sequence comprises an active zone for generating a light radiation, which can be formed as a quantum well structure, for example. In the case of a so-called sapphire chip, a sapphire substrate is used.

For generating white light, a semiconductor chip which emits in the blue or ultraviolet spectral range can be used, a layer of a wavelength-converting material being arranged on said semiconductor chip. The conversion material, which can be applied to the finished processed semiconductor chip by volume potting, for example, serves to convert part of the primary blue-violet light radiation into a secondary light radiation of lower energy, for example a yellow light radiation. The different light radiations can be superimposed to form a white light radiation.

The performance of optoelectronic semiconductor chips can be impaired by different effects. In the case of a sapphire chip, for example, the envisaged coupling-out of light radiation from the semiconductor can be reduced on account of total internal reflection at the interface. A reduction in power can furthermore originate from a reabsorption of generated primary radiation at a quantum well structure. Furthermore, a semiconductor layer sequence grown onto a substrate with the aid of a deposition or epitaxy process can have defects and strains on account of a lattice mismatch.

The object of the present invention is to specify a solution for an improved optoelectronic semiconductor chip.

This object is achieved by means of the features of the independent patent claims. Further advantageous embodiments of the invention are specified in the dependent claims.

In accordance with one aspect of the invention, an optoelectronic semiconductor chip is proposed. The optoelectronic semiconductor chip comprises a semiconductor layer sequence having an active zone for generating a light radiation and a conversion structure. The conversion structure comprises conversion regions for converting the generated light radiation. Non-converting regions are arranged between the conversion regions. In particular, the conversion regions can be in direct contact with the semiconductor layer sequence.

In the case of the optoelectronic semiconductor chip, part of the primary light radiation generated in the active zone can be converted into at least one secondary light radiation in a different wavelength range, in particular a light radiation of lower energy, with the aid of the conversion regions. The primary and the at least one secondary light radiation can be superimposed. In this way, the optoelectronic semiconductor chip can emit a light radiation whose color is predefined by the superimposition of the partial radiations.

The conversion structure used for radiation conversion can be produced before or else in the context of the formation of the semiconductor layer sequence, i.e. between the formation of individual layers of the semiconductor layer sequence. In this way, the conversion regions of the conversion structure can be arranged in the region of the semiconductor layer sequence or adjoin the semiconductor layer sequence. As a result, part of the primary light radiation generated in the active zone can be converted into the at least one secondary light radiation directly in the semiconductor chip and hence relatively rapidly. As a result, it is possible to reduce a reabsorption of the generated primary radiation in the active zone. Furthermore, the optoelectronic semiconductor chip can be smaller or thinner than a semiconductor chip having an externally applied wavelength-converting layer.

The conversion structure present in the region of the semiconductor layer sequence can furthermore afford further advantages. By way of example, the conversion structure can bring about an improved coupling-out efficiency of light radiation from the semiconductor layer sequence. Moreover, it is possible to influence the formation of the semiconductor layer sequence, which can be effected with the aid of a deposition process, for example an epitaxy process. In this way, the semiconductor layer sequence can be deposited with an altered, in particular reduced, defect density. These effects obtainable with the aid of the conversion structure, i.e. an improved radiation extraction and an improved layer growth, can be comparable to the effects when using a substrate having a structured surface.

The arrangement of the conversion structure in the region of the semiconductor layer sequence furthermore makes it possible to obtain an effective cooling of the conversion regions. As a result, the conversion regions can have a high efficiency and durability.

A further effect achievable with the conversion structure consists in altering the emission profile of the optoelectronic semiconductor chip in a targeted manner. In this way, it is possible, for example, to coordinate the emission profile of the semiconductor chip with a predefined emission characteristic. This effect is possible particularly in the case of such an embodiment of the semiconductor chip in which the conversion regions and/or the non-converting regions are arranged in a regular grid or spacing grid. A rectangular or hexagonal grid is appropriate, for example. Instead of a regular arrangement, however, an irregular or random arrangement of the conversion regions and/or of the non-converting regions can also be provided.

The optoelectronic semiconductor chip can be, in particular, a light emitting diode chip or LED chip comprising a semiconductor layer sequence. The semiconductor layer sequence is preferably based on a III-V compound semiconductor material. The semiconductor material is for example a nitride compound semiconductor material such as AlₙIn₁₋ₙ₋ₘGaₘN or a phosphide compound semiconductor material such as AlₙIn₁₋ₙ₋ₘGaₘP or else an arsenide compound semiconductor material such as AlₙIn₁₋ₙ₋ₘGaₘAs, wherein in each case 0≦n≦1, 0≦m≦1 and n+m≦1. In this case, the semiconductor layer sequence can comprise dopants and additional constituents. For the sake of simplicity, however, only the essential constituents of the crystal lattice of the semiconductor layer sequence, that is to say Al, As, Ga, In, N or P, are indicated, even if these can be replaced and/or supplemented in part by small amounts of further substances.

The conversion regions of the conversion structure can be arranged in a plane parallel to the active zone of the semiconductor layer sequence. The non-converting regions can then lie in the same plane between the conversion regions. The conversion regions can furthermore comprise a conversion material for converting the light radiation generated in the active zone. The conversion material can be a ceramic conversion material, for example. One possible example is a conversion material based on a garnet which is correspondingly doped. By way of example, the conversion material is a cerium-doped yttrium aluminum garnet, YAG for short, and/or a lutetium aluminum garnet, LuAG for short, and/or a lutetium yttrium aluminum garnet, LuYAG for short. Alternatively, other conversion materials can also be used, such as, for example, an Eu²⁺-doped alkaline earth metal silicon nitride and/or an alkaline earth metal aluminum silicon nitride, wherein the alkaline earth metal is barium or calcium or strontium, for example. By way of example, the conversion regions can also comprise a correspondingly doped semiconductor material, for example a II-VI compound semiconductor material or a III-V compound semiconductor material such as AlInGaN. It is also possible for the conversion regions to comprise a plurality of different conversion materials.

In the non-converting regions present between the conversion regions, it is possible to arrange one non-converting material, i.e. material not designed for radiation conversion, or a plurality of such materials. Depending on the configuration of the optoelectronic semiconductor chip, material or semiconductor material of the semiconductor layer sequence and/or substrate material of a substrate of the semiconductor chip can be involved, for example. In particular, the non-converting regions can be filled with the material of the semiconductor layer sequence and/or the substrate material to the extent of at least 50% or 90% or completely.

The optoelectronic semiconductor chip can be designed for emitting a white light radiation, for example. For this purpose, provision can be made for the active zone of the semiconductor layer sequence to generate a primary light radiation in the blue to ultraviolet spectral range. Furthermore, provision can be made for the conversion regions of the conversion structure or a conversion material used for the conversion regions to convert part of the blue-violet light radiation into a secondary light radiation of longer wavelength, for example in the yellow spectral range. White light radiation can be generated by additive color mixing. It is also possible for the conversion regions to convert the primary light radiation into a secondary light radiation in a different spectral range, or into a plurality of secondary light radiations in different spectral ranges. The emission of light radiations in the colors red, green and/or amber is appropriate, for example. For the emission of different secondary light radiations, the conversion regions can comprise different conversion materials, for example in the form of a material mixture or in the form of layers composed of different conversion materials.

In a further embodiment, the conversion regions of the conversion structure are separated from one another. In this configuration, the conversion regions can be present in the form of separate structure elements. The converting structure elements can be arranged alongside one another and can be spaced apart and thereby separated from one another by the non-converting regions. In this case, non-converting regions can enclose individual structure elements, and merge into one another. The separate configuration of the conversion structure with separated structure elements affords the possibility of bringing about one or more of the advantageous effects described above in a reliable manner. By way of example, such a configuration in which the individual structure elements are arranged in a regular spacing grid can be appropriate for this purpose. However, an irregular arrangement is also possible.

Preferably, in this case, at least two of the separate structure elements are arranged alongside one another in a plane parallel to the active zone of the semiconductor layer sequence. In particular, all the separate structure elements can be arranged alongside one another in a plane parallel to the active zone of the semiconductor layer sequence.

It is furthermore possible for the conversion regions separated from one another to be formed in such a way that the individual conversion regions additionally enclose in each case (at least) one non-converting region. In this configuration, by way of example, converting structure elements having a circumferential shape, for example frame-shaped or annular structure elements, can be present. One non-converting material or a plurality of such materials can be arranged in the enclosed non-converting regions, in a manner comparable to the non-converting regions present between the conversion regions.

In an alternative embodiment, the conversion regions of the conversion structure form a continuous layer enclosing the non-converting regions. The layer is perforated by the non-converting regions, and is present as a perforated layer. In this configuration, in a comparable manner provision can be made for the individual non-converting regions to be arranged in a regular grid. However, an irregular arrangement is also possible.

In a further embodiment, the optoelectronic semiconductor chip comprises a substrate. The conversion structure or the conversion regions thereof are surrounded by the substrate and the semiconductor layer sequence. The substrate, which can serve as a carrier of the semiconductor chip, can be for example a light-transmissive or transparent substrate, for example a sapphire substrate. In this embodiment, in which the conversion regions can adjoin the substrate and the semiconductor layer sequence, the conversion structure can bring about for example a reduced total internal reflection between the semiconductor layer sequence and the substrate, and as a result an improved coupling of light radiation into the substrate.

In a further embodiment, the conversion structure is arranged within the semiconductor layer sequence. The conversion structure enclosed in the semiconductor layer sequence in this configuration can provide, for example, for the conversion of part of the primary light radiation generated in the active zone into the (at least one) secondary light radiation relatively rapidly. This radiation portion is therefore no longer subject to reabsorption in the active zone.

In a further embodiment, the optoelectronic semiconductor chip comprises a substrate. The conversion structure is arranged in the region of a side of the semiconductor layer sequence facing away from the substrate. In this embodiment, the conversion structure can enable for example a reduced total internal reflection at that side of the semiconductor layer sequence which faces away from the substrate, and as a result an improved coupling-out of light radiation at this side of the semiconductor layer sequence.

The conversion regions of the conversion structure can be formed from an individual layer. In this case, the layer can comprise an individual conversion material for converting the generated light radiation, or else a material mixture composed of different conversion materials for radiation conversion.

In an alternative embodiment, the conversion regions of the conversion structure are formed in a multilayered fashion. By way of example, the conversion regions can comprise layers composed of different conversion materials. In a further possible multilayered configuration, the conversion regions of the conversion structure can comprise a first layer and a second layer adjoining the first layer, wherein the first layer comprises (at least) one conversion material for covering the light radiation generated in the active zone. In this case, the second layer can at least partly encapsulate the first layer, and can thereby serve as a protective layer for protecting the first layer. As a result, it is possible to prevent for example an impediment of the at least one conversion material in the context of the production of the semiconductor chip. It is possible for the first layer and/or the second layer to comprise a plurality of layers or partial layers, and therefore to be present in the form of a layer sequence.

In particular, the second layer can encapsulate the first layer to an extent such that there is no direct contact or there is a reduced contact between the first layer and the semiconductor layer sequence. The second layer can comprise for example a material which prevents direct growth of the semiconductor layer sequence on the conversion regions. For this purpose, the second layer can comprise for example a metal nitride or a metal oxide, such as aluminum oxide or aluminum nitride or titanium oxide, or a semiconductor nitride or a semiconductor oxide, such as SiN and/or SiO₂.

In a further embodiment, the optoelectronic semiconductor chip comprises a substrate having a structured surface at one side. The conversion structure and the semiconductor layer sequence are formed on the side of the substrate having the structured surface. In this configuration, the structured surface of the substrate together with the conversion structure can bring about one or more of the advantages described above, for example an improved coupling-out efficiency, an improved layer growth, etc. It is also possible for individual or a plurality of the effects described above to be additionally intensified by the presence of the structured substrate surface.

The structured surface can be formed for example in the form of elevations projecting relative to the rest of the substrate side. In this connection, the above-described configuration of the conversion structure can be appropriate, for example, according to which the conversion regions form a continuous layer perforated by the non-converting region. In this case, the conversion regions can be present between the elevations of the substrate or surround the elevations. In this way, the elevations can be arranged in the non-converting regions and can serve as non-converting intermediate regions. Alternatively, the conversion structure can comprise conversion regions which are separated from one another and which are arranged on the individual elevations of the substrate. A further variant consists in the substrate having a surface structure in the form of depressions which are formed in the relevant substrate side and in which separate conversion regions are arranged.

In particular, the conversion regions can be arranged between the elevations of the substrate such that the elevations of the substrate and the conversion regions are flush at the end side and form a planar end side. The semiconductor layer sequence can then be applied on the planar end side, for example.

In a further embodiment, the optoelectronic semiconductor chip comprises a plurality of conversion structures arranged in different planes. Said conversion structures can each comprise conversion regions for converting the generated light radiation, non-converting regions being arranged between said conversion regions. The individual conversion structures can be formed in accordance with the configurations described above, and can likewise afford the advantages presented above, possibly in intensified form owing to the plurality of conversion structures. It is possible for the conversion structures present in different planes to be formed in a matching fashion, such that, for example, the conversion regions of the conversion structures have the same shape and comprise the same conversion material. Alternatively, the conversion structures can be formed in a manner deviating from one another. By way of example, different shapes of the conversion structures and/or the use of different conversion materials are/is possible, such that the individual conversion structures can generate secondary light radiations in different spectral ranges.

In accordance with a further aspect of the invention, a method for producing an optoelectronic semiconductor chip is proposed. The method comprises providing a substrate, and forming a conversion structure on the substrate. The conversion structure comprises conversion regions for converting a light radiation, non-converting regions being provided between said conversion regions. The method furthermore comprises forming semiconductor layers on the substrate and on the conversion regions of the conversion structure. In this way, a semiconductor layer sequence having an active zone for generating a light radiation is formed, which light radiation is convertible with the aid of the conversion regions of the conversion structure.

Forming the semiconductor layers can be carried out with the aid of a deposition process, for example an epitaxy process. The conversion structure formed previously, which can comprise at least one suitable conversion material, makes it possible to influence the deposition process in a manner comparable to a substrate having a surface structure. In this way, the semiconductor layer sequence can be formed with an altered, in particular reduced, defective density. It is possible, for example, for the layer growth to proceed more slowly on the conversion regions of the conversion structure than between or outside the conversion regions. Furthermore, forming the conversion structure used for radiation conversion makes it possible to dispense with externally applying a wavelength-converting layer. The semiconductor chip produced by the method can therefore have a smaller thickness than a semiconductor chip having such an externally applied layer.

During the operation of the semiconductor chip produced in this way, the conversion structure can bring about further effects besides radiation conversion. Depending on the configuration of the semiconductor chip, the conversion structure can enable for example a higher coupling-out efficiency of light radiation from the semiconductor layer sequence, and a reduced reabsorption of light radiation in the active zone. Furthermore, the conversion structure can serve for example to impart a predefined emission profile to the semiconductor chip.

The conversion structure can be formed in such a way that the conversion regions are separated from one another. In this case, separate structure elements can be present, which possibly additionally enclose non-converting regions. Alternatively, it is possible to form the conversion structure in such a way that the conversion regions merge into one another and form a continuous layer enclosing the non-converting regions.

In a further embodiment, the substrate is provided having an initial layer at one side. The conversion structure and the semiconductor layers are formed on the substrate coated in this way, or on the initial layer of the substrate. The initial layer can be for example an initial layer which is provided for the semiconductor layer sequence and which can serve as a seed layer or buffer layer for the remaining, subsequently applied semiconductor layers of the semiconductor layer sequence. In this way, the conversion structure can be formed in the form of a structure embedded in the semiconductor layer sequence. In this configuration, the conversion structure can bring about for example relatively rapid conversion of part of the light radiation generated in the active zone.

In a further embodiment, the substrate used for forming the semiconductor layer sequence is removed. For the case of using a substrate which is coated with an initial layer and on which the conversion structure and the subsequent semiconductor layers are formed, just the actual substrate (without the initial layer) can be removed. Before the removal of the substrate, provision can be made for transferring the semiconductor layer sequence to a further substrate, which can serve as a carrier of the semiconductor chip.

In a further embodiment, the conversion regions of the conversion structure are formed in a multilayered fashion. By way of example, the conversion regions can be formed with layers composed of different conversion materials. A configuration comprising a first layer and a second layer adjoining the first layer is furthermore possible, wherein the first layer comprises at least one conversion material. In this case, provision can be made for the second layer to at least partly surround or enclose the first layer. The use of the second layer affords the possibility, for example, of preventing direct deposition or growth of the semiconductor layer sequence on the conversion regions of the conversion structure, such that lateral coalescence can take place over the conversion regions. In this way, the deposition process can be influenced in a targeted manner, and the semiconductor layer sequence can be formed with an altered or lower defect density. Furthermore, the second layer can additionally or alternatively serve as a protective layer in order for example to prevent an impediment of a conversion material during the process of forming the semiconductor layer sequence. It is possible for the second layer to comprise a plurality of layers or partial layers and therefore to be present in the form of a layer sequence. The second layer can comprise SiN and/or SiO₂, for example. The first layer can also comprise a plurality of layers or partial layers.

In a further embodiment, the substrate is provided having a structured surface at one side. The conversion structure and the semiconductor layer sequence are formed on the side of the substrate having the structured surface. The structured substrate surface together with the conversion structure can enable one or more of the effects described above, for example an improved deposition or layer growth, or contribute to a corresponding intensification of an effect.

In the case of the conversion structure formed on the substrate or on the initial layer of the substrate, the non-converting regions can firstly be present in the form of cutouts which expose partial regions of the substrate or of the initial layer. In the case of a conversion structure composed of separate conversion regions (or structure elements), individual conversion regions can be enclosed by cutouts. In this case, cutouts which merge into one another can form a common cutout structure enclosing individual conversion regions. If appropriate, the conversion regions themselves can additionally enclose individual cutouts. In the case of a conversion structure in the form of a continuous layer that is perforated in places, by contrast, separate cutouts are present. In both variants, the subsequent process of forming the semiconductor layers can result in semiconductor material being formed in or introduced into the cutouts and the cutouts thereby being filled.

With the use of a substrate having a structured surface, by contrast, the conversion structure can be formed on the substrate in such a way that partial regions (or elevations) of the substrate partly or completely project into the non-converting regions. Therefore, the subsequent process of forming the semiconductor layers can have the effect that the non-converting regions are only partly filled or are not filled with semiconductor material.

In a further embodiment, at least one further conversion structure is formed in the context of forming semiconductor layers for forming the semiconductor layer sequence. The further conversion structure can also comprise conversion regions for converting the generated light radiation, non-converting regions being provided between said conversion regions. In this configuration, the further conversion structure can be produced between the formation of successive semiconductor layers. In this way, the optoelectronic semiconductor chip can be produced with a plurality of conversion structures arranged in different planes.

It is pointed out that aspects and details mentioned with regard to the semiconductor chip can also be applied to the production method. Furthermore, the optoelectronic semiconductor chip can be formed with further structures and layers besides the structures and components described above. They can include for example contact elements, through contacts, connecting layers, mirror layers, buffer layers, passivation layers, etc.

The advantageous embodiments and developments of the invention as explained above and/or represented in the dependent claims can—except for example in cases of clear dependencies or incompatible alternatives—be applied individually or else in arbitrary combination with one another.

The above-described properties, features and advantages of this invention and the way in which they are achieved will become clearer and more clearly understood in association with the following description of exemplary embodiments which are explained in greater detail in association with the schematic drawings, in which:

FIGS. 1 to 3 show the production of an optoelectronic semiconductor chip having a conversion structure for radiation conversion, comprising separated conversion regions, in each case in a schematic lateral illustration;

FIG. 4 shows a schematic plan view illustration of a conversion structure having separated conversion regions;

FIG. 5 shows a flow chart of a method for producing an optoelectronic semiconductor chip;

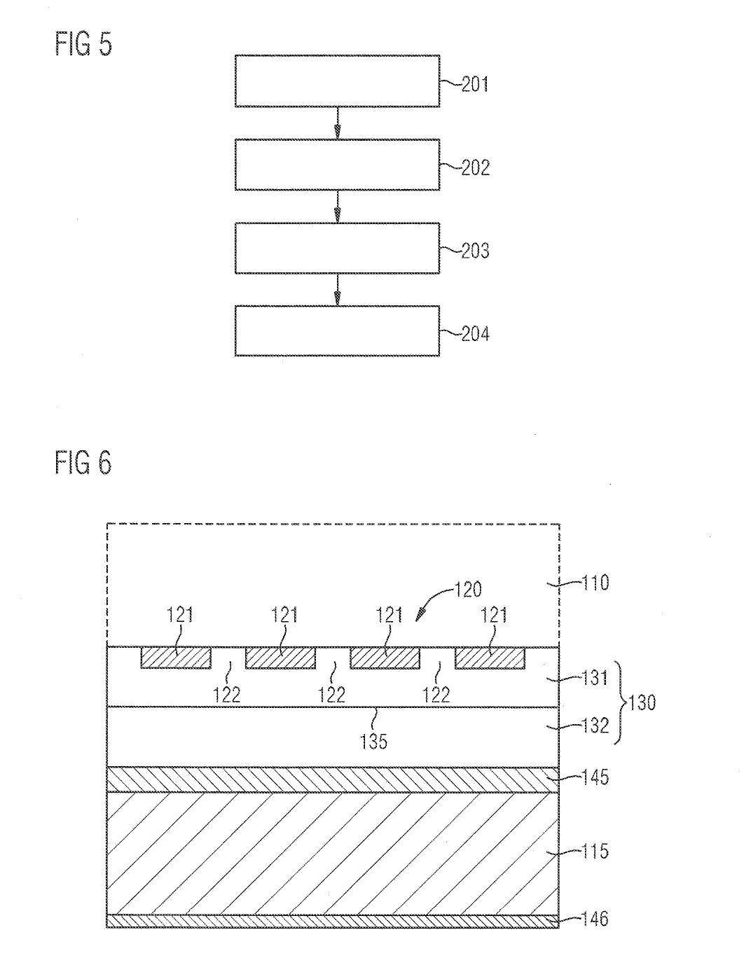

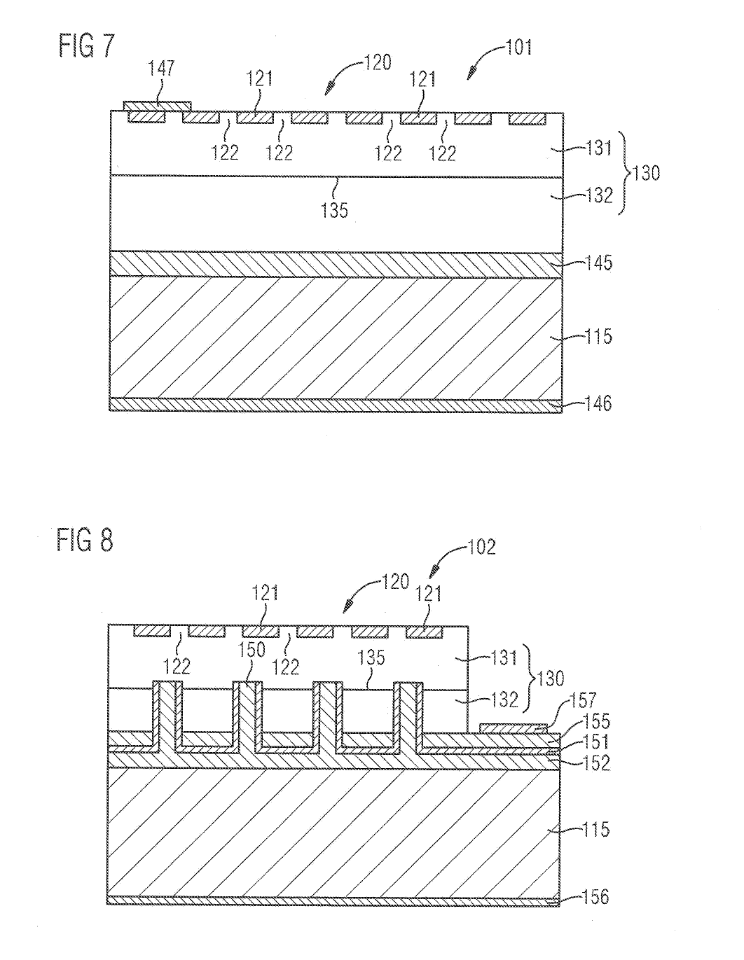

FIGS. 6 and 7 show the production of a further optoelectronic semiconductor chip having a conversion structure, wherein a semiconductor layer sequence formed on a substrate is transferred to a carrier substrate, in each case in a schematic lateral illustration;

FIG. 8 shows a schematic lateral illustration of a further optoelectronic semiconductor chip having a conversion structure, wherein the semiconductor chip has through contacts;

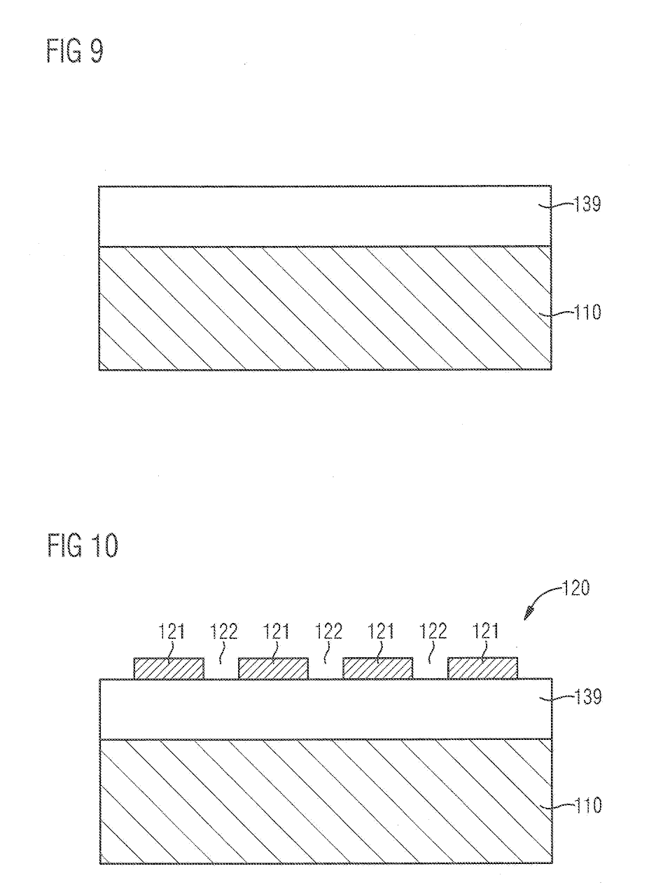

FIGS. 9 to 12 show the production of a further optoelectronic semiconductor chip having a conversion structure, which is enclosed in a semiconductor layer sequence, in each case in a schematic lateral illustration;

FIGS. 13 and 14 show schematic lateral illustrations of further optoelectronic semiconductor chips having a conversion structure enclosed in a semiconductor layer sequence;

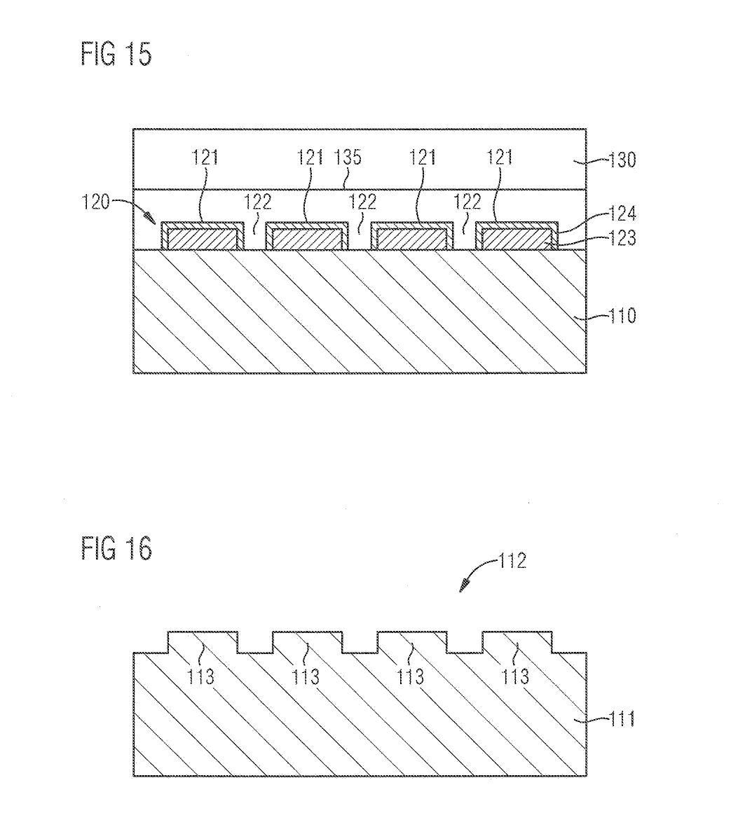

FIG. 15 shows the production of an optoelectronic semiconductor chip having a conversion structure, which comprises conversion regions having an encapsulation, in a schematic lateral illustration;

FIGS. 16 to 18 show the production of an optoelectronic semiconductor chip having a conversion structure, wherein a substrate having a structured surface is used and the conversion structure is formed with separated conversion regions arranged on elevations of the structured surface, in each case in a schematic lateral illustration;

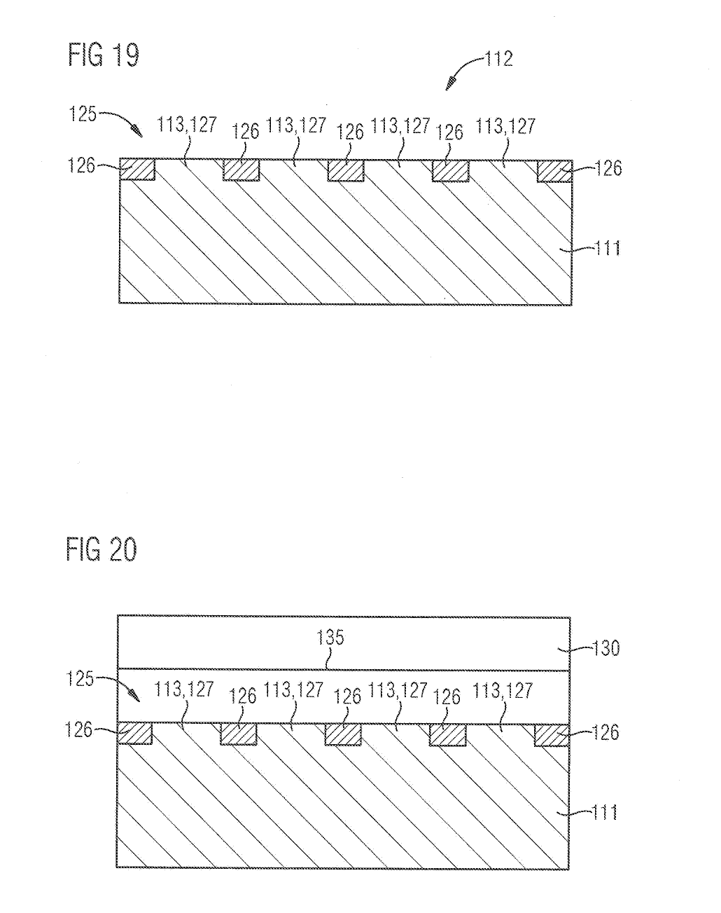

FIGS. 19 and 20 show the production of an optoelectronic semiconductor chip having a conversion structure, wherein a substrate having a structured surface is used and the conversion structure is formed in the form of a layer perforated in places, in each case in a schematic lateral illustration;

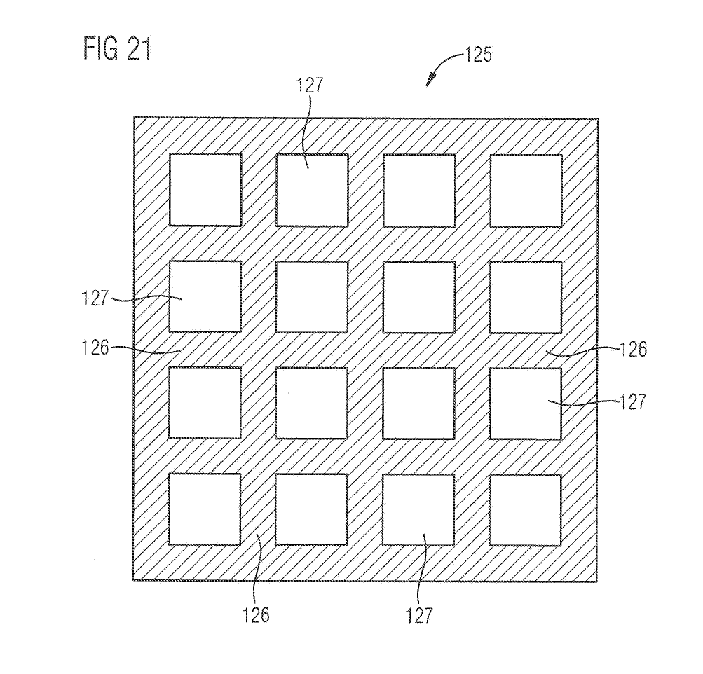

FIG. 21 shows a schematic plan view illustration of a conversion structure in the form of a layer perforated in places;

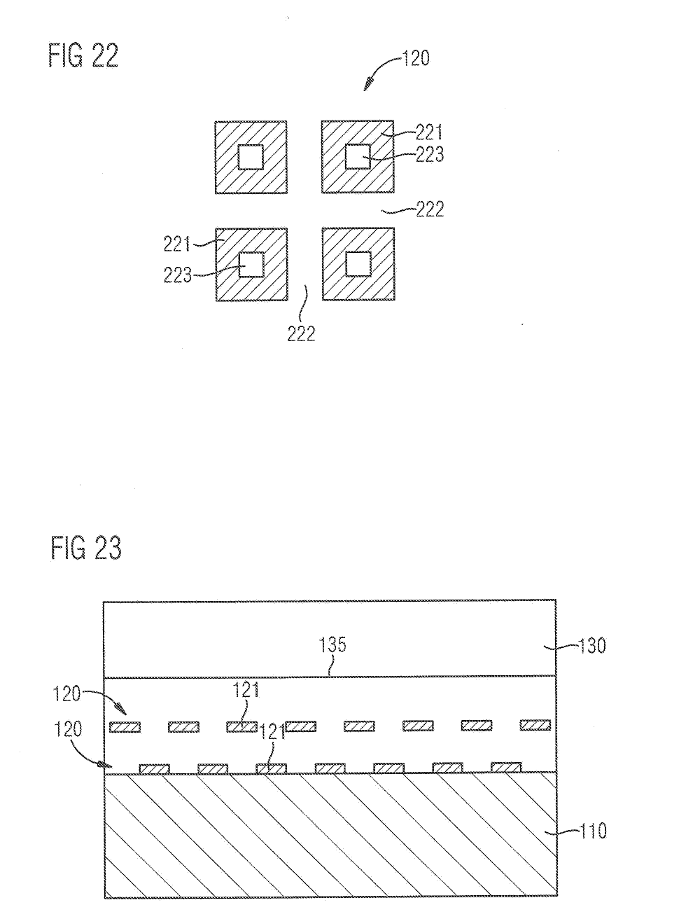

FIG. 22 shows a schematic plan view illustration of a conversion structure having separated conversion regions, which have a circumferential form; and

FIG. 23 shows the production of an optoelectronic semiconductor chip having a plurality of conversion structures arranged in different planes.

Embodiments of optoelectronic semiconductor chips and associated production methods are described on the basis of the following schematic figures. The optoelectronic semiconductor chips, which can be light emitting diode chips, in particular, comprise a conversion structure 120, 125 for converting a light radiation, said conversion structure extending along a plane. The conversion structure 120, 125 can positively influence both the production of the semiconductor chips and the functioning of the finished semiconductor chips.

In the context of production, processes known from semiconductor technology and from the manufacture of optoelectronic semiconductor chips can be carried out, and customary materials can be used, and so these will be discussed only in part. Moreover, besides illustrated and described processes, if appropriate, it is possible to carry out further method steps for completing the semiconductor chips. In the same way, the semiconductor chips can comprise further components, structures and/or layers besides structures shown and described. It is furthermore pointed out that the figures are not true to scale. In this regard, components and structures shown in the figures may be illustrated with exaggerated size or size reduction in order to afford a better understanding.

FIGS. 1 to 3 show (as excerpts) in a schematic lateral sectional view the production of a first optoelectronic semiconductor chip 100. Method steps carried out in the method are additionally summarized in the flowchart in FIG. 5, to which reference is likewise made below.

In the method, a step 201 (cf. FIG. 5) involves providing a substrate 110 shown in FIG. 1. The substrate 110 can be formed for example from a transparent material, for example sapphire. The substrate 110 has an unstructured smooth surface at one side, or main side, on which further components of the semiconductor chip 100 are subsequently formed.

A further step 202 (cf. FIG. 5) involves forming a conversion structure 120 on the smooth side of the substrate as shown in FIG. 1. The conversion structure 120 comprises a plurality of separate conversion regions 121, which are arranged in a plane alongside one another on the substrate 110. The individual conversion regions 121 are also designated hereinafter as structure elements 121. As shown in FIG. 1, the structure elements 121 are separated from one another by regions 122, which are designated hereinafter as intermediate regions 122. In the method stage in FIG. 1, the intermediate regions 122 form cutouts at which the substrate 110 is exposed. In the case of the conversion structure 120, the intermediate regions 122 present as cutouts merge into one another and form a common cutout structure enclosing individual structure elements 121 (cf. the plan view illustration in FIG. 4).

The structure elements 121 comprise a conversion material for radiation conversion. In this way, during the operation of the semiconductor chip 100, part of a primarily generated light radiation can be converted into a secondary light radiation, in particular of lower energy. The conversion material of the structure elements 121 can be for example a ceramic conversion material, for example based on a garnet. It is also possible for the conversion material to be based on a semiconductor material, for example a II-VI compound semiconductor material.

Forming the structure elements 121 of the conversion structure 120 that are arranged alongside one another can be carried out in various ways. By way of example, a continuous planar layer of the conversion material can be formed on the substrate side and subsequently structured into the individual conversion regions 121. The coating of the substrate side can be carried out for example with the aid of a deposition process or some other application process. A further possibility is applying or bonding on a layer of the conversion material using an auxiliary carrier, which is subsequently removed. It is possible, furthermore, to apply the conversion material to the substrate 110 using a mask formed on the substrate 110, wherein the mask is subsequently removed together with conversion material situated on the mask, in order to form the separate structure elements 121 (lift-off process).

The structure elements 121 can have a rectangular cross-sectional shape, as shown in FIG. 1. As viewed from above, the structure elements 121 can have a rectangular or square plan view shape, as is indicated in the plan view illustration of the conversion structure 120 in FIG. 4. It is pointed out that only an excerpt from the conversion structure 120 is illustrated in FIG. 4 and the other figures.

Furthermore, as is likewise shown in FIG. 4, the structure elements 121 can be positioned alongside one another in a matrix-like fashion in the form of rows and columns in a regular spacing grid. Lateral dimensions of the structure elements 121 and spacings of the spacing grid can be for example in the range of one or a plurality of micrometers or else in the range of a hundred or hundreds of nanometers. Such indications can also apply to a height or thickness of the structure elements 121. Furthermore, the semiconductor chip 100 can be realized for example with a number of structure elements 121 in the single- to twelve-digit range.

Apart from a rectangular cross-sectional and plan view form, the structure elements 121 of the conversion structure 120 can also be formed with other shapes and contours. By way of example, provision can be made for the structure elements 121 to have a triangular or curved or arched contour in cross section. As viewed from above, the structure elements 121 can have a circular shape, for example. Furthermore, it is possible for a different grid, for example a hexagonal grid, to be provided instead of the rectangular grid shown in FIG. 4. However, other arrangements of the structure elements 121, as well as irregular or random arrangements, are also possible. Furthermore, the structure elements 121 can be formed, if appropriate, non-uniformly with shapes deviating from one another.

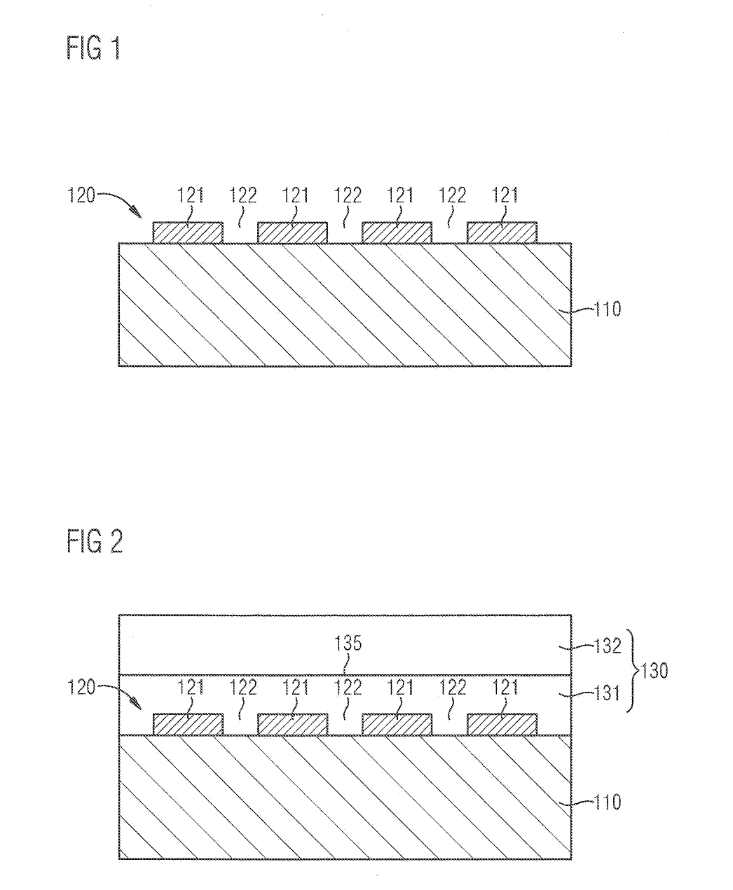

In a subsequent step 203 (cf. FIG. 5), as shown in FIG. 2, a semiconductor layer sequence 130 is formed on the side of the substrate 110 with the conversion structure 120. Forming the semiconductor layer sequence 130 on the substrate 110 and on the structure elements 121 is carried out with the aid of a deposition process, in particular an epitaxy process, in the course of which individual semiconductor layers are grown successively. The semiconductor layer sequence 130, which can be based on a III-V compound semiconductor material such as GaN, for example, has an active zone 135 indicated in FIG. 2. The active zone 135 is designed to generate a (primary) light radiation when an electric current is applied. The active zone 135 can comprise for example a quantum well structure, in particular multi quantum well structure.

The semiconductor layer sequence 130 furthermore comprises differently doped semiconductor layers 131, 132, between which the active zone 135 is arranged. By way of example the semiconductor layer 131 can be n-conducting, and the semiconductor layer 132 can be p-conducting. However, inverse dopings with respect thereto are also possible. The two semiconductor layers 131, 132 can each comprise a plurality of partial layers. Adjoining the substrate 110 and the structure elements 121, the semiconductor layer sequence 130 can furthermore comprise a buffer or seed layer (not illustrated).

Forming the semiconductor layer sequence 130 has the consequence that semiconductor material of the semiconductor layer sequence 130 is also arranged in regions around the individual structure elements 121 and thus in the intermediate regions 122 between the structure elements 121. In the case of the optoelectronic semiconductor chip 100, said regions 122 therefore constitute non-converting regions in which no conversion of (primary) light radiation is effected.

The structure elements 121 situated on the substrate 100 make it possible to provide suitable growth conditions for the deposition process, as a result of which the semiconductor layer sequence 130 or the seed layer thereof can be grown with an altered, in particular reduced, defect density. The occurrence of such defects is essentially a consequence of deviating lattice structures between the substrate 110 and the semiconductor material grown thereon. The structure elements 121 can influence the deposition process for example in such a way that the layer growth proceeds more slowly on or in the region of the structure elements 121 than in regions of the substrate 110 between and outside the structure elements 121.

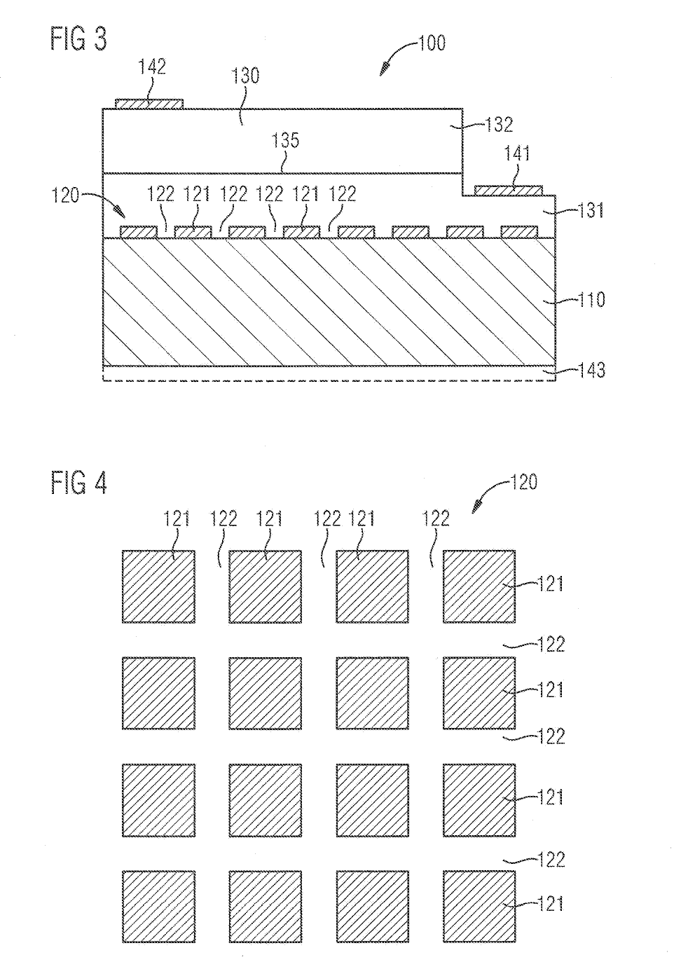

After this, further processes for completing the optoelectronic semiconductor chip 100 shown in FIG. 3 are carried out, which are combined in a further step 204 in the flow chart in FIG. 5. They include structuring the semiconductor layer sequence 130 for the purpose of partly exposing the semiconductor layer 131, such that the semiconductor layer 131 is contactable. Furthermore, metallic contacts 141, 142 are formed on the exposed section of the semiconductor layer 131 and on the semiconductor layer 132, which contacts are linked to the semiconductor layers 131, 132. During the operation of the semiconductor or light emitting diode chip 100, an electric current can be applied via the contacts 141, 142 to the semiconductor layers 131, 132 present on both sides of the active zone 135.

The method can be carried out in such a way that a plurality of semiconductor chips 100 are formed jointly or in a parallel manner on the substrate 110. In this regard, a further process that can be carried out in the context of step 204 is a singulation process. This process involves severing the substrate 110 and the semiconductor layer sequence 130 arranged thereon in order to provide individual semiconductor chips 100.

In the case of the semiconductor chip 100, the structure elements 121 of the conversion structure 120 are surrounded by the substrate 110 and the semiconductor layer sequence 130. For the semiconductor chip 100, by way of example, mounting in the orientation shown in FIG. 3 on a carrier or a circuit board, also designated as submount, may be appropriate (not illustrated). In this case, the side of the semiconductor layer sequence 130 with the contact 142 constitutes a front side of the semiconductor chip 100, via which part of the light radiation generated by the semiconductor chip 100 can be emitted (light exit side). By contrast, that side of the substrate 110 which faces away from the semiconductor layer sequence 130 constitutes a rear side provided for mounting. On this side of the substrate 110, as indicated in FIG. 3, a layer 143 can furthermore be formed in the context of step 204. The layer 143 can comprise a metallic layer and/or a reflection or antireflection layer. The side flanks of the substrate 110 can also be coated, if appropriate, metallically and/or with a reflection or antireflection layer (not illustrated). The layer 143 makes it possible to mechanically connect the semiconductor chip 100 to the carrier for example by soldering using a solder. The contacts 141, 142 of the semiconductor chip 100 can be connected to mating contacts of the carrier with the aid of bonding wires.

During the operation of the semiconductor chip 100 mounted in this way, a primary light radiation is generated in the active zone 135 and is emitted in the direction of the side or front side with the contact 142, and in the direction of the substrate 110 or the conversion structure 120. With the aid of the structure elements 121 of the conversion structure 120, part of the primary light radiation can be converted into a secondary light radiation, in particular of longer wavelength, which can be emitted by the structure elements 121.

During the operation of the semiconductor chip 100, light radiation (i.e. the primary and secondary light radiation) is furthermore coupled into the transparent substrate 110. The light radiation coupled into the substrate 110 can be reflected at the layer 143 acting as a mirror (and at the possibly coated side flanks of the substrate 110) and can be coupled into the semiconductor layer sequence 130 again.

The radiation-converting structure elements 121 can have the effect that an altered, preferably reduced, total internal reflection is present at the transition between the semiconductor layer sequence 130 and the transparent substrate 110. As a result, an altered or higher extraction of light radiation from the semiconductor layer sequence 130 and coupling into the substrate 110 are possible. The extraction efficiency is dependent on parameters such as, for example, the refractive index, the shape and size of the structure elements 121. A high extraction can be obtained in particular for the case where the structure elements 121, as indicated above, have a triangular or arched cross-sectional shape, for example.

The light radiation emitted by the semiconductor chip 100, or its color, results from a superimposition of the primary radiation generated in the active zone 135 and the secondary radiation generated by the structure elements 121 of the conversion structure 120. The semiconductor chip 100 can be designed for example for emitting a white light radiation. For this purpose, the active zone 135 can be designed for generating a primary radiation in the blue to ultraviolet spectral range, and the structure elements 121 can be designed for generating a secondary radiation in the yellow spectral range. One possible conversion material for the conversion elements 121 for generating a yellow secondary radiation is cerium-doped yttrium aluminum garnet, for example. The blue-violet and yellow light radiation together produce the white light radiation.

On account of the conversion structure 120, the semiconductor chip 100 can be formed with a smaller thickness than a conventional semiconductor chip in which the radiation conversion is realized by means of a layer applied externally to the chip or to the front side thereof.

The configuration of the semiconductor chip 100 comprising the converting structure elements 121 as shown in FIG. 3 furthermore makes it possible for part of the primary radiation generated in the active zone 135 to be converted into the secondary radiation of longer wavelength directly in the semiconductor chip 100 and consequently relatively rapidly. In contrast to the primary radiation, when passing through the active zone 135, the secondary radiation is not subject to absorption in the active zone 135 or in the quantum well structure. Therefore, reabsorption in the active zone 135 can take place to a lesser extent in the case of the semiconductor chip 100 than in the case of a conventional semiconductor chip comprising an external layer for radiation conversion, in which conventional semiconductor chip primary radiation generated in the associated active zone can, on account of reflection(s), pass back to the active zone and be absorbed here.

In the case of the semiconductor chip 100, the structure elements 121 of the conversion structure 120 are surrounded by the substrate 110 and the semiconductor layer sequence 130. Effective cooling of the structure elements 121 is possible as a result. Consequently, the structure elements 121 can have a high efficiency and durability.

The structure elements 121 of the conversion structure 120 can furthermore serve to predefine the emission profile of the semiconductor chip 100. The emission profile is dependent, inter alia, on the fact that light radiation can be reflected within the semiconductor chip 100 possibly multiply at corresponding interfaces—for example at the front side, at the transition between the semiconductor layer sequence 130 and the substrate 110, and at the rear side or the layer 143 provided here. In this case, the light radiation also passes through the structure elements 121 arranged within the semiconductor chip 100. Said structure elements, as a periodic structure with the presence of a suitable shape, can bring about a targeted influencing of the light radiation and thus of the emission profile of the semiconductor chip 100. As a result, it is possible, for example, to coordinate the emission profile with a predefined emission characteristic.

Instead of arranging the semiconductor chip 100 in the orientation shown in FIG. 3 with the substrate 110 on a carrier, the semiconductor chip 100 can also be a so-called flip-chip provided for mounting in an orientation rotated by 180 degrees with respect to FIG. 3. In this configuration, the contacts 141, 142 of the semiconductor chip 100 can be electrically and mechanically connected to mating contacts of a carrier for example by soldering using a solder. In this case, that side of the transparent substrate 110 which faces away from the semiconductor layer sequence 130 forms the front side of the semiconductor chip 100. By contrast, the side of the semiconductor layer sequence 130 with the contact 142 constitutes the rear side of the semiconductor chip 100.

In the case of a configuration as a flip-chip, the layer 143 and the coating of the side flanks of the substrate 110 are omitted. In this way, light radiation which is generated during the operation of the semiconductor chip 100 and enters the transparent substrate 110 can be emitted via the front side and the side flanks of the substrate 110. Furthermore, provision can be made for the contact 142, in a departure from FIG. 3, to be formed in a manner extending substantially over the entire side or rear side of the semiconductor layer 132. As a result, the contact 142 can act as a mirror in order to reflect light radiation in the direction of the substrate 110.

In the configuration of the semiconductor chip 100 as a flip-chip, aspects described above can be present in the same way. With the aid of the conversion structure 120, part of the primary radiation generated in the active zone 135 can be converted into the secondary radiation of longer wavelength. The structure elements 121 of the conversion structure 120 enable advantages such as, for example, an improved extraction of light radiation from the semiconductor layer sequence 130 and coupling into the substrate 110. Compared with a conventional flip-chip comprising a converting layer applied externally to the chip or to the transparent substrate thereof, the semiconductor chip 100 can have a smaller thickness, and lower radiation absorption in the active zone 135 can take place. Moreover, the structure elements 121 can influence the emission profile of the semiconductor chip 100 in a targeted manner. For further details, reference is made to the explanations above.

Further optoelectronic semiconductor chips and possible methods for producing them are described with reference to the following figures. It is pointed out that with regard to details which have already been described and which relate to similar or corresponding components and features, possible advantages, generation of a white light radiation, etc., reference is made to the explanations above. Furthermore, it is possible that aspects which are mentioned with regard to one of the following embodiments can also be applied to other embodiments.

FIGS. 6 and 7 show in a schematic lateral view the production of a further optoelectronic semiconductor chip 101 using a transfer process. The semiconductor chip 101 can be a so-called thin-film chip. The production method involves firstly forming, in the manner described above, on the provided substrate 110 the conversion structure 120 having the structure elements 121 arranged alongside one another and separated by intermediate regions 122, and the semiconductor layer sequence 130 (steps 201 to 203, cf. FIG. 2).

The subsequent step 204 involves connecting the semiconductor layer sequence 130 or the semiconductor layer 132 thereof to a further substrate 115 via a conductive intermediate layer 145, as shown in FIG. 6. The substrate 115, which serves as carrier substrate in the case of the semiconductor chip 101, comprises a conductive material, for example a doped semiconductor material such as germanium, for example. The intermediate layer 145 can comprise one or a plurality of metallic layers, for example a mirror layer and a bonding layer.

In the context of step 204, removal of the substrate 110, which is used only for the growth of the semiconductor layer sequence 130, is furthermore carried out, as indicated in FIG. 6. In the case of a transparent substrate 110 composed of sapphire, such as was described above, the substrate 110 can be detached for example using a laser (laser lift-off process). Alternatively, it is possible to remove the substrate 110 by thinning, for example by grinding away and/or etching. Such a procedure is possible for example in the case of a substrate 110 composed of silicon. During the removal of the substrate 110, removal of a part of the semiconductor layer sequence 130 and/or of the structure elements 121 of the conversion structure 120 can also take place, if appropriate.

As is furthermore shown in FIG. 6, a metallic layer 146 is formed on that side of the further substrate 115 which faces away from the intermediate layer 145. This can be carried out before or after the production of the connection between the semiconductor layer sequence 130 and the substrate 115 (via the intermediate layer 145). The metallic layer 146 serves as a rear-side contact 146 of the semiconductor chip 101. After the removal of the substrate 110, furthermore, as shown in FIG. 6, a metallic contact 147 is formed on that side of the semiconductor layer sequence 130 which faces away from the intermediate layer 145, or on the semiconductor layer 131. Said contact serves as a front-side contact 147 of the semiconductor chip 101.

The method described with reference to FIGS. 6 and 7 can likewise be carried out in such a way that a plurality of semiconductor chips 101 are formed jointly. Therefore, in this case, too, in the context of step 204, a singulation for providing separate semiconductor chips 101 can be carried out.

In the case of the semiconductor chip 101 in FIG. 7, the structure elements 121 of the conversion structure 120 are situated in the region of that side of the semiconductor layer sequence 130 which faces away from the substrate 115. This side constitutes the front side of the semiconductor chip 101, via which front side part of the light radiation generated by the semiconductor chip 101 can be emitted (light exit side). The contact 147 which contacts the semiconductor layer 131 is arranged on this side. The other contact 146 is electrically connected to the other semiconductor layer 132 via the conductive substrate 115 and the intermediate layer 145. In this way, during the operation of the semiconductor chip 101, an electric current can be applied via the contacts 146, 147 to the semiconductor layers 131, 132 present on both sides of the active zone 135.

The semiconductor chip 101 can be electrically and mechanically connected to a mating contact of a carrier (submount) with the aid of the rear-side contact 146 for example by soldering. The front-side contact 147 can be connected to a further mating contact of the carrier by means of a bonding wire (not illustrated).

During the operation of the semiconductor chip 101 mounted in this way, a primary light radiation is generated in the active zone 135 of the semiconductor layer sequence 130, said light radiation being emitted in the direction of the front side of the semiconductor chip 101 and thus in the direction of the conversion structure 120, and in the direction of the intermediate layer 145. With the aid of the structure elements 121, part of the primary light radiation can be converted into the secondary light radiation, which is superimposed on the primary light radiation. The intermediate layer 145 acts as a mirror at which light radiation can be reflected.

Besides the radiation conversion, the structure elements 121 can likewise enable an improved coupling-out of light radiation from the semiconductor layer sequence 130, in the present case at the front side of the semiconductor chip 101. Moreover, other advantages from among those mentioned above, such as a small thickness of the semiconductor chip 101, for example, can be present. Furthermore, as a periodic structure, the structure elements 121 can bring about a targeted influencing of the emission profile of the semiconductor chip 101. Furthermore, with the aid of the structure elements 121, part of the primary radiation generated in the active zone 135 can be converted relatively rapidly into the secondary radiation of longer wavelength. As a result, a reduced radiation absorption can occur in comparison with a conventional semiconductor chip having a layer applied externally to a front side, in the case of which semiconductor chip primary radiation generated in the associated active zone can pass back to the active zone on account of reflection(s). The arrangement of the structure elements 121 in the region of the semiconductor layer sequence 130 furthermore enables an effective cooling of the structure elements 121.

FIG. 8 shows a further configuration of a semiconductor or thin-film chip 102 formed with the aid of a transfer process. In this case, after the formation of the conversion structure 120 and the semiconductor layer sequence 130 on the provided substrate 110 (steps 201 to 203, cf. FIG. 2), in the context of the subsequent step 204, a connection between the semiconductor layer sequence 130 and the further substrate 115 is produced, which connection is more complex compared with FIG. 6. It comprises the constituent parts described below.

As is shown in FIG. 8, the semiconductor layer 132 is adjoined by a conductive layer 155, which can serve as a current spreading and/or mirror layer. Furthermore, a plurality of through contacts 150 are present. The through contacts 150 comprise cutouts which extend vertically through the conductive layer 155, the semiconductor layer 132, the active zone 135 and into the semiconductor layer 131 and which are filled at the edge with an insulation layer 151 and with a conductive layer 152 surrounded by the insulation layer 151. The conductive layer 152 makes contact with the semiconductor layer 131, and is connected to the further substrate 115. Outside the through contacts 150, the layers 152, 151, 155 are arranged one above another in the form of a layer stack. The two conductive layers 152, 155 are separated from one another by the insulation layer 151. A connection between the conductive layer 152 and the substrate 115 can be produced via a conductive connecting layer (not illustrated).

In order to complete the semiconductor chip 102 shown in FIG. 8, after the production of the connection structure described above, a metallic layer 156 is formed on the substrate 115, said metallic layer serving as a rear-side contact 156 of the semiconductor chip 102. Furthermore, the substrate 110 is removed in the manner described above, as a result of which the semiconductor layer sequence 130 or the front side thereof is exposed. This is followed by structuring of the semiconductor layer sequence 130 for partly exposing the conductive layer 155, such that the conductive layer 155 is contactable. Moreover, a metallic contact 157 is formed on the exposed section of the conductive layer 155.

The method described with reference to FIG. 8 can likewise be carried out in such a way that a plurality of semiconductor chips 102 are formed jointly. In the context of step 204, therefore, singulation for providing separate semiconductor chips 102 can be carried out.

In the case of the semiconductor chip 102 in FIG. 8 as well, the structure elements 121 of the conversion structure 120 are situated at that side of the semiconductor layer sequence 130 which faces away from the substrate 115 and which constitutes the front or light exit side of the semiconductor chip 102. The contact 157 arranged laterally with respect to the semiconductor layer sequence is electrically connected to the semiconductor layer 132 via the conductive layer 155. The other contact 156 is electrically connected to the semiconductor layer 131 via the substrate 115, the conductive layer 152 and the through contacts 150. In this way, during the operation of the semiconductor chip 102, an electric current can be applied via the contacts 156, 157 to the semiconductor layers 131, 132 arranged on both sides of the active zone 135.

The semiconductor chip 102 can be electrically and mechanically connected to a mating contact of a carrier (submount) with the aid of the rear-side contact 156 for example by soldering. The front-side contact 157 can be connected to a further mating contact of the carrier by means of a bonding wire (not illustrated).

During the operation of the semiconductor chip 102, a primary light radiation is generated in the active zone 135 of the semiconductor layer sequence 130, said light radiation being emitted in the direction of the front side of the semiconductor chip 101 and thus in the direction of the structure elements 121, and in the direction of the conductive layer 155. With the aid of the structure elements 121, part of the primary light radiation can be converted into the secondary light radiation, which is superimposed on the primary light radiation. The conductive layer 155 acts as a mirror at which light radiation can be reflected. The converting structure elements 121 enable an improved coupling-out of light radiation at the front side of the semiconductor layer sequence 130. Furthermore, the semiconductor chip 102 can have a smaller thickness than in the case of a configuration having an externally applied conversion layer. The conversion elements 121 furthermore enable the presence of a lower reabsorption of light radiation in the active zone 135, and influencing of the emission profile of the semiconductor chip 102. The arrangement of the structure elements 121 in the region of the semiconductor layer sequence 130 furthermore enables an effective cooling of the structure elements 121.

A semiconductor chip can furthermore be formed in such a way that the conversion structure 120 is completely enclosed in the semiconductor layer sequence 130. Possible embodiments are described in greater detail below.

FIGS. 9 to 12 show in a schematic lateral sectional view the production of a further optoelectronic semiconductor chip 103, the construction of which substantially corresponds to the semiconductor chip 100 in FIG. 3. The method involves providing the substrate 110 shown in FIG. 9 (for example composed of sapphire), which substrate is already coated with an initial layer 139 on a (smooth) side of the substrate (step 201). The initial layer 139, which is grown by a deposition or epitaxy process on the substrate 110, can constitute the above-described seed or buffer layer of the semiconductor layer sequence 130 to be produced. The initial layer 139 can comprise a III-V compound semiconductor material such as GaN or AlN, for example.

Afterward, as shown in FIG. 10, a conversion structure 120 is formed on the coated substrate 110 (step 202). The conversion structure 120 comprises a plurality of separate structure elements 121 which are arranged in a plane alongside one another on the initial layer 139. The individual structure elements 121 are separated from one another by intermediate regions 122. In the method stage in FIG. 10, the intermediate regions 122 form cutouts at which the initial layer 139 is exposed. The intermediate regions 122 present as cutouts merge into one another and form a common cutout structure enclosing individual structure elements 121 (cf. the plan view illustration in FIG. 4).

The structure elements 121 comprise a conversion material suitable for radiation conversion, for example a ceramic conversion material or a semiconductor material. Forming the structure elements 121 can be carried out by one of the methods described above, for example. For example, it is possible to form a continuous layer of the conversion material on the initial layer 139 and subsequently to structure it, or to apply a conversion material using a mask formed on the initial layer 139, followed by a lift-off process. The structure elements 121 can once again be arranged in a regular spacing grid. Moreover, the same dimensions and cross-sectional and plan view shapes that were described above can be present. Furthermore, an irregular or random arrangement of the structure elements 121 can also be provided instead of a regular arrangement.

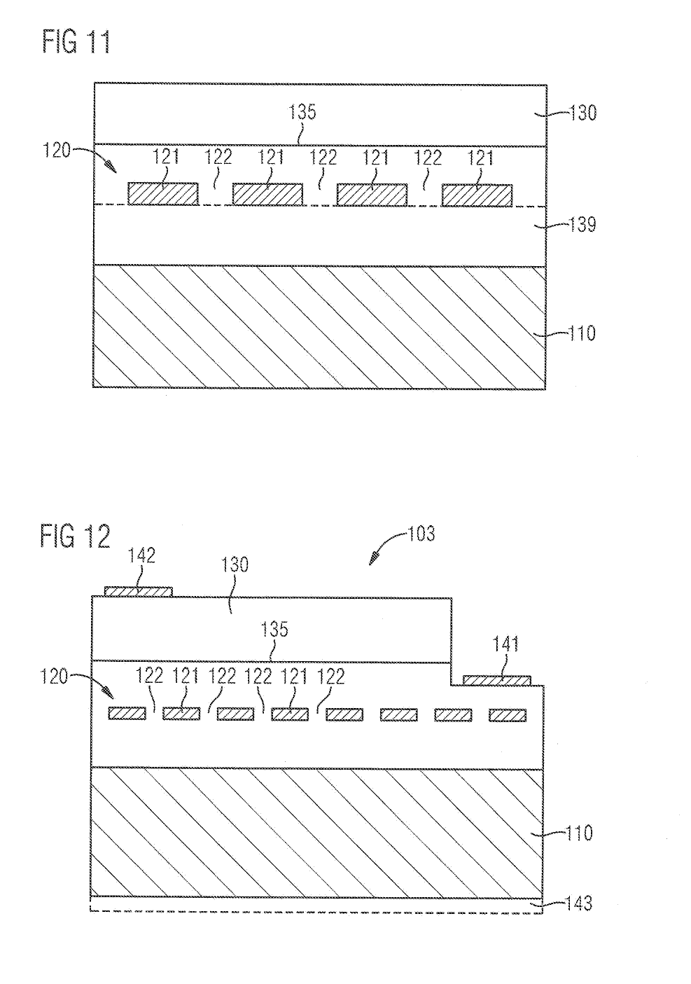

After this, further semiconductor layers are formed on the initial layer 139 and/or the structure elements 121 of the conversion structure 120, in order that the semiconductor layer sequence 130 shown in FIG. 11 and comprising the initial layer 139 is formed on the substrate 110 (step 203). These remaining semiconductor layers of the semiconductor layer sequence 130 can likewise be based on a III-V compound semiconductor material, for example GaN. The semiconductor layer sequence 130 has an active zone 135 for generating a (primary) light radiation and differently doped layers on both sides of the active zone 135. As a result of the conversion structure 120 being formed after the formation of the initial layer 139, the conversion structure 120 is arranged within the semiconductor layer sequence 130. In particular, the semiconductor layer sequence 130 surrounds the conversion structure 120 or the conversion regions 121 completely all around, that is to say at all sides. The conversion structure 120 is then only in contact with the semiconductor layer sequence 130, for example.

The application of the further semiconductor layers is carried out with the aid of a deposition or epitaxy process. Once again semiconductor material of the semiconductor layer sequence 130 is also arranged in regions around the individual structure elements 121 and thus in the intermediate regions 122, as a result of which such regions constitute non-converting regions in the case of the semiconductor chip 103. The structure elements 121 of the conversion structure 120 that are situated on the initial layer 139 in this configuration, too, afford the possibility of influencing the layer growth. By way of example, slower growth can take place on or in the region of the structure elements 121 than in regions of the initial layer 139 between and outside the structure elements 121. As a result, the layers applied to the initial layer 139 and thus the semiconductor layer sequence 130 can have an altered or reduced defect density.

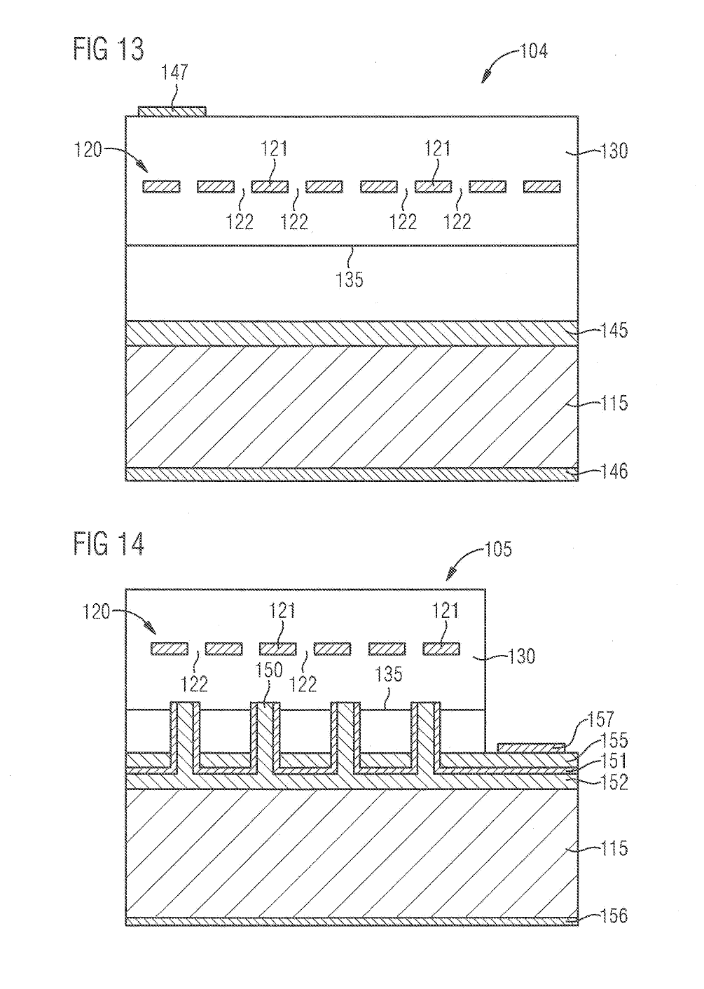

Afterward, in an analogous manner, processes for completing the semiconductor chip 103 shown in FIG. 12 are carried out (step 204). They include structuring the semiconductor layer sequence 130, forming contacts 141, 142, if appropriate providing the substrate 110 with a layer 143, and carrying out a singulation process. Apart from the structure elements 121 embodied in the semiconductor layer sequence 130, the semiconductor chip 103 has the same construction as the semiconductor chip 100 shown in FIG. 3. Therefore, substantially the same functioning as in the case of the semiconductor chip 100 can be present. Moreover, the semiconductor chip 103 can be used in the orientation shown in FIG. 12 or as a flip-chip in an orientation rotated by 180 degrees on a carrier.

During the operation of the semiconductor chip 103, a primary light radiation is generated in the active zone 135 and is emitted in the direction of the side with the contact 142, and in the direction of the substrate 110 or the conversion structure 120. With the aid of the structure elements 121, part of the primary light radiation can be converted into a secondary light radiation, in particular of longer wavelength, which secondary light radiation is superimposed on the primary light radiation. On account of the structure elements 121 situated within the semiconductor layer sequence 130, the structure elements 121 possibly cannot bring about an improvement in the extraction efficiency of light radiation from the semiconductor layer sequence 130 and coupling into the transparent substrate 110. However, the embedded configuration affords the possibility of converting part of the primary radiation generated in the active zone 135 into the secondary radiation even more rapidly, as a result of which it is possible to obtain a further improvement with regard to the reabsorption taking place in the active zone 135. The embedded arrangement of the structure elements 121 in the semiconductor layer sequence 130 furthermore makes it possible to obtain an effective cooling of the structure elements 121.

The rest of the functioning of the semiconductor chip 103 corresponds to the functioning of the semiconductor chip 100. By way of example, light radiation coupled into the substrate 110 can be reflected at the layer 143 acting as a mirror, and can be coupled into the semiconductor layer sequence 130 again. In this case, the side of the semiconductor layer sequence 130 with the contact 142 can be the front or light exit side via which part of the light radiation generated by the semiconductor chip 103 can be emitted. In the case of a configuration as a flip-chip, the contact 142 can be formed in a manner extending substantially over the entire rear side of the semiconductor layer sequence 130 in order to reflect light radiation in the direction of the substrate 110, and the light radiation generated by the semiconductor chip 103 can be emitted via the front side and the side flanks of the substrate 110. The further aspects and advantages associated with the conversion structure 120, can likewise apply in the case of the semiconductor chip 103, for example the presence of a small thickness and the influencing of the emission profile of the semiconductor chip 103.

The arrangement of the conversion structure 120 integrated in the semiconductor layer sequence 130 can be employed in an analogous manner in interaction with a transfer process. For elucidation, FIG. 13 shows a schematic lateral illustration of a further optoelectronic semiconductor chip 104, which has substantially the same construction as the semiconductor chip 101 shown in FIG. 7. The semiconductor chip 104 can be produced in a manner comparable to the semiconductor chip 101 by virtue of the fact that, after steps 201 to 203 have been carried out for producing the arrangement shown in FIG. 11, in step 204 the semiconductor layer sequence 130 is connected to the further substrate 115 via the conductive intermediate layer 145, the substrate 110 used for the growth of the semiconductor layer sequence 130 is removed, and the metallic contacts 146, 147 are formed.

Substantially the same functioning as in the case of the semiconductor chip 101 can be present in the case of the semiconductor chip 104. The side of the semiconductor layer sequence 130 with the contact 147 constitutes the front or light exit side of the semiconductor chip 104. During the operation of the semiconductor chip 104, a primary light radiation is generated in the active zone 135 and is emitted in the direction of the front side or in the direction of the conversion structure 120, and in the direction of the intermediate layer 145. With the aid of the conversion structure 120, part of the primary light radiation can be converted into the secondary light radiation which is superimposed on the primary light radiation. The intermediate layer 145 acts as a mirror at which light radiation can be reflected. The enclosed configuration of the conversion structure 120 makes it possible that part of the primary radiation can be converted into the secondary radiation even more rapidly in comparison with the semiconductor chip 101, such that a further improvement is achievable with regard to the reabsorption taking place in the active zone 135. Furthermore, the semiconductor chip 104 can have a small thickness, and the emission profile can be influenced with the aid of the structure elements 121 of the conversions structure 120. The embedded arrangement of the structure elements 121 in the semiconductor layer sequence 130 furthermore enables an effective cooling of the structure elements 121.

FIG. 14 shows a further embodiment of a semiconductor chip 105 formed with the aid of a transfer process, said semiconductor chip having substantially the same construction as the semiconductor chip 102 shown in FIG. 8. The semiconductor chip 105 can be produced in a manner comparable to the semiconductor chip 102 by virtue of the fact that after steps 201 to 203 have been carried out for producing the arrangement shown in FIG. 11, in step 204 the connecting structure with the substrate 115 as shown in FIG. 14 is formed, the metallic layer 156 is formed, the substrate 110 is removed, the semiconductor layer sequence 130 is structured, and the metallic contact 157 is formed.

The functioning of the semiconductor chip 105 can substantially correspond to the semiconductor chip 102. That side of the semiconductor layer sequence 130 which faces away from the substrate 115 constitutes the front or light exit side of the semiconductor chip 105. During the operation of the semiconductor chip 105, a primary light radiation is generated in the active zone 135 and is emitted in the direction of the front side or in the direction of the conversion structure 120, and in the direction of the conductive layer 155. With the aid of the conversion structure 120, part of the primary light radiation can be converted into the secondary light radiation which is superimposed on the primary light radiation. The conductive layer 155 acts as a mirror at which light radiation can be reflected. The enclosed conversion structure 120 makes it possible that part of the primary radiation can be converted into the secondary radiation even more rapidly in comparison with the semiconductor chip 102, such that a further improvement is achievable with regard to the reabsorption taking place in the active zone 135. Furthermore, the semiconductor chip 105 can have a small thickness, and the emission profile can be influenced with the aid of the structure elements 121 of the conversion structure 120. The embedded arrangement of the structure elements 121 in the semiconductor layer sequence 130 furthermore enables an effective cooling of the structure elements 121.

In the case of the above-described semiconductor chips 100, 101, 102, 103, 104, 105 in FIGS. 3, 7, 8, 12, 13, 14, the conversion structure 120 used for radiation conversion, or its conversion regions 121, can comprise an individual conversion material, such that only one secondary radiation is generated. However, it is also possible for the conversion regions 121 or the layer produced beforehand and subsequently structured into the conversion regions 121 (step 202) to comprise different conversion materials, for example in the form of a material mixture composed of different conversion materials. In this way, the conversion regions 121 can emit different secondary radiations from different spectral ranges. By way of example, the emission of secondary radiations in the colors red, green and/or amber is appropriate. The aspects mentioned above in association with one secondary radiation can analogously apply to the generation of different secondary radiations. In particular, in such a configuration, too, a white light radiation can be generated by the superimposition of different partial radiations.

The conversion structure 120 used for radiation conversion, or the conversion regions 121, can furthermore—as described above—be constructed from an individual layer or alternatively from a plurality of layers, i.e. two or more layers. For elucidation of the last-mentioned variant, FIG. 15 shows a lateral sectional view of a substrate 110 during the production of an optoelectronic semiconductor chip, wherein a multilayered conversion structure 120 and a semiconductor layer sequence 130 having an active zone 135 are arranged on a (smooth) side of the substrate.

The conversion structure 120 shown in FIG. 15 comprises individual structure elements 121 separated by intermediate regions 122 and each comprising a first layer 123 and a second layer 124 adjoining the first layer 123. The first layer 123, which is arranged on the substrate 110, can be partly encapsulated by the second layer 124, such that there is no direct contact, or alternatively there is a reduced contact between the first layer 123 and the semiconductor layer sequence 130.

The first layer 123 can comprise a suitable conversion material with the aid of which part of the primary radiation generated in the active zone 135 can be converted into a secondary radiation. This can involve one of the abovementioned materials, for example a ceramic conversion material or a semiconductor material. The second layer 124 can comprise a material which makes it possible to prevent direct growth of the semiconductor layer sequence 130 on the structure elements 121, such that a lateral coalescence over the structure elements 121 can take place instead. By way of example, epitaxial lateral coalescence (FLOG, epitaxial lateral overgrowth) is possible. In this way, the deposition process can likewise be influenced in a suitable way, such that the semiconductor layer sequence 130 can be formed with an altered or lower defect density. An appropriate material for this purpose for the second layer 124 is SiN or SiO₂, for example. The encapsulation in the form of the second layer 124 can furthermore serve as a protective layer for protecting the first layer 123 in order for example to prevent impairment of the first layer 123 during the formation of the semiconductor layer sequence 130.

The multilayered structure elements 121 can be produced (step 202) for example by virtue of the fact that firstly separate sections of the first layer 123 are formed on the substrate 110. This can be carried out by the formation or application of a continuous layer 123 and subsequent structuring thereof, or with the aid of a lift-off process. Afterward, a second continuous layer 124 can be applied to the substrate 110 and the layer sections 123 and can be structured. This can be followed by the formation of the semiconductor layer sequence (step 203), and the further processing (step 204, not illustrated).

Abovementioned details concerning shapes and dimensions can apply to the multilayered structure elements 121 in the same way. By way of example, in a departure from the rectangular cross-sectional shape shown in FIG. 15, the multilayered structure elements 121 can be formed with a different cross-sectional shape, for example a triangular or curved cross-sectional shape. As viewed from above, the multilayered structure elements 121 can have for example a rectangular shape, or a different shape such as a circular shape, for example. Furthermore, an arrangement in a spacing grid can be provided (cf. FIG. 4). However, an irregular or random arrangement is also possible.

Both the semiconductor chip 100 from FIG. 3 and the semiconductor chips 101, 102 in FIGS. 7 and 8 can be formed with the conversion structure 120 having the multilayered structure elements 121 as shown in FIG. 15. It is also possible for the multilayered structure elements 121 to be embedded in a semiconductor layer sequence 130, or for the semiconductor chips 103, 104, 105 in FIGS. 12, 13, 14 to be formed with such a conversion structure 120. In this case, the layers 123, 124 are formed on the initial layer 139 in an analogous manner before the further processing of the semiconductor layer sequence 130 is carried out. In this configuration, too, the second layer 124 can prevent direct growth on the structure elements 121 and can bring about lateral coalescence. Furthermore, the first layer 123 can be protected against impairment.

Besides the construction described with reference to FIG. 15, multilayered structure elements 121 can also be realized with a different construction in step 202. By way of example, the first layer 123 can comprise different conversion materials, for example in the form of a material mixture, in order to emit different secondary radiations. It is also possible for the second layer 124 to be formed from a plurality of (partial) layers and therefore to be present in the form of a layer sequence. It is also possible merely to provide an arrangement of first and second layers 123, 124 one above another, such that no partial regions of the second layer 124 are present laterally with respect to the first layer 123. In a further possible configuration, the first layer 123 in each of the structure elements 121 can be completely surrounded or encapsulated by the second layer 124. This affords the possibility, for example, of protecting the first layer 123 against damage in the case where the substrate 110 is possibly removed. With regard to the generation of different secondary radiations, it may furthermore be appropriate, for example, to form the first layer 123 and the second layer 124 from different conversion materials. In this case, it is possible merely to provide an arrangement of the layers 123, 124 one above another. Furthermore, it is possible for the first layer 123 encapsulated by the second layer 124 to comprise a plurality of (partial) layers composed of different conversion materials arranged one above another. Such configurations should be regarded as possible examples which can be replaced by other multilayered embodiments.

In the embodiments described above, the substrate 110 has a planar surface at the side on which components of semiconductor chips are formed. However, it is also possible to use a surface structure, as described below.

FIGS. 16 to 18 show an alternative production method in a lateral sectional view. In the method, as shown in FIG. 16, a substrate 111 is provided instead of the substrate 110 (step 201). The substrate 111 has a structured surface 112 at the side provided for forming further chip components. The structured surface 112 comprises a plurality of elevations 113 which are arranged alongside one another and which project relative to the rest of the substrate side. The substrate 111 can otherwise be formed like the substrate 110 described above, and comprise for example a transparent material, for example sapphire.

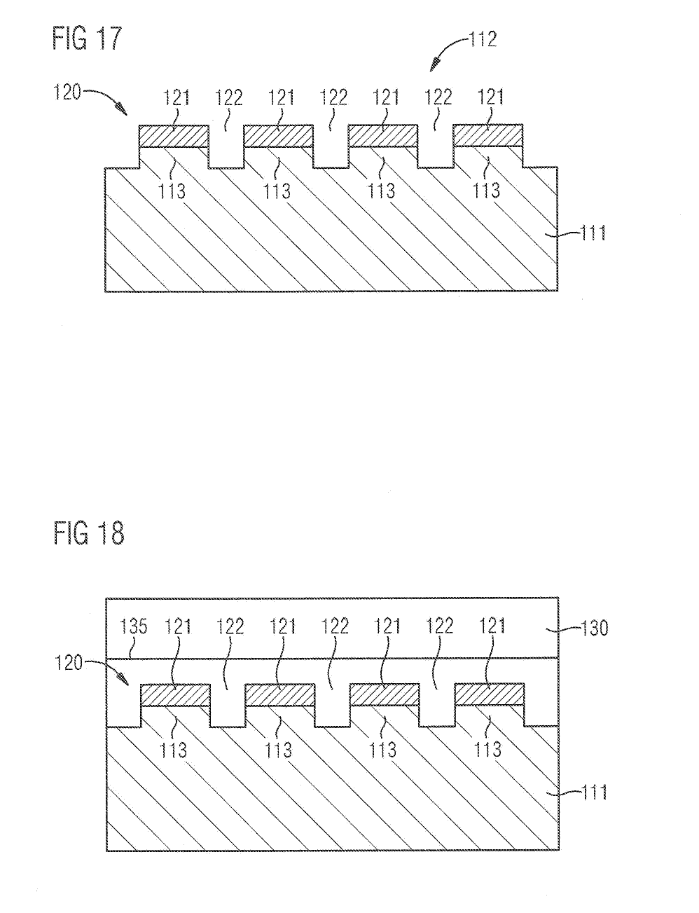

Afterward, as shown in FIG. 17, a conversion structure 120 is formed on the structured surface 112 of the substrate 111 (step 202). The conversion structure 120 has (once again) a plurality of separate conversion regions or structure elements 121. The latter are arranged alongside one another on the individual elevations 113 of the substrate 111. In this configuration, too, the individual structure elements 121 are separated from one another by intermediate regions 122 merging into one another, initially in the form of cutouts. With regard to their lateral dimensions and their position, the intermediate regions 122 can substantially correspond to the substrate regions present between the elevations 113.

The structure elements 121 can be formed in accordance with one of the embodiments described above. By way of example, the structure elements 121 can comprise a conversion material for radiation conversion, for example a ceramic conversion material or a semiconductor material. The conversion structure 120 can be produced for example by the formation or application of a continuous layer of the conversion material and subsequent structuring, or with the aid of a lift-off process. It is also possible for the structure elements 121, as indicated above, to be formed from a plurality of conversion materials and/or in a multilayered fashion, for example in accordance with FIG. 15.

Afterward, as shown in FIG. 18, a semiconductor layer sequence 130 having an active zone 135 is formed on the side of the substrate 111 having the structured surface 112 and the conversion structure 120 (step 203). The formation of the semiconductor layer sequence 130 on the substrate 111 and the structure elements 121 is carried out with the aid of a deposition process, in particular an epitaxy process. In this case, semiconductor material of the semiconductor layer sequence 130 is also arranged in regions around the individual elevations 113 and structure elements 121 and thus in the intermediate regions 122. The presence of the structured substrate surface 112, together with the structure elements 121 of the conversion structure 120, can influence the layer growth in a suitable way. By way of example, it is possible to bring about slower growth in the region of the elevations 113 and structure elements 121 than in regions between and outside the elevations 113 and structure elements 121. Therefore, the semiconductor layer sequence 130 or the seed layer thereof can be grown with an altered, in particular reduced, defect density.

Afterward, further processes for completing a semiconductor chip emerging from the arrangement in FIG. 18 are carried out (step 204, not illustrated). In this case, above-described processes and a singulation can be carried out, and a semiconductor chip comparable to the semiconductor chip 100 from FIG. 3 can therefore be produced. It is also possible to remove the substrate 111 or to carry out a transfer process, as a result of which semiconductor chips comparable to the semiconductor chips 101, 102 in FIGS. 7, 8 can be produced. In these semiconductor chips, the removal of the substrate 111 can result in the presence of a structured front or light exit side.

In the case of a semiconductor chip comprising the substrate 111 and the conversion structure 120 or a semiconductor chip produced using the substrate 111, above-described advantages and effects can likewise be present—improvement of the extraction efficiency, reduction of the reabsorption, influencing of the emission profile, small thickness, effective cooling, etc.—besides the improved layer growth. If appropriate, the combination of structured surface 112 and conversion structure 120 can bring about an additional intensification of one or more effects, for example the improvement of the layer growth and of the extraction efficiency.

The structure elements 121 and the elevations 113 of the substrate 111 can have a rectangular cross-sectional shape as shown in FIGS. 16 to 18. In a departure therefrom, however, other, for example triangular or curved, cross-sectional shapes can also be provided for the structure elements 121 and/or the elevations 113. The elevations 113 and thus the structure elements 121 can be arranged in a regular rectangular spacing grid, and can furthermore have a rectangular geometry as viewed from above, such that the plane view shape shown in FIG. 4 can once again be present. It is also possible for the structure elements 121 and/or the elevations 113 to have plan view shapes deviating therefrom, such as a circular shape, for example, and for arrangements deviating therefrom to be present, such as a hexagonal arrangement or an irregular or random arrangement, for example. Lateral dimensions and a height of the structure elements 121 and/or of the elevations 113 and also spacings of the spacing grid can be for example in the range of one or a plurality of micrometers, or else in the range of a hundred or hundreds of nanometers. Furthermore, the substrate 111 per semiconductor chip to be produced can be formed for example with a number of elevations 113 in the single- to twelve-digit range.

FIGS. 19 and 20 show in a lateral sectional view a further method using the above-described substrate 111 having the structured surface 112 present at one side of the substrate. The method involves, after providing the substrate 111 (step 201), forming a conversion structure 125 provided for radiation conversion on the structured substrate side of the substrate 111 (step 202), as is illustrated in FIG. 19. The conversion structure 125 comprises conversion regions 126 which are arranged in a plane and which are present between the elevations 113 of the substrate 111 and surround the elevations 113. The conversion regions 126 merge into one another and form a continuous layer. The layer composed of the conversion regions 126 therefore encloses intermediate regions 127 in which the layer is interrupted. The elevations 113 of the substrate 111 are arranged in the intermediate regions 127. In the case of a semiconductor chip emerging therefrom, the intermediate regions 127 constitute non-converting regions in which no conversion of (primary) light radiation takes place.

The shape and geometry of the conversion structure 125 can substantially depend on the shape of the structured surface 112 of the substrate 111 or the shape of the elevations 113. The elevations 113 can have in cross section the rectangular shape shown in FIG. 19, and likewise a rectangular contour as viewed from above. Furthermore, the elevations 113 can be arranged in a regular rectangular spacing grid. In this way, the conversion structure 125 can have the plan view shape shown (as an excerpt) in FIG. 21. With reference to FIG. 21 it becomes clear that the conversion regions 126 form a continuous conversion layer which encloses the intermediate regions 127 and is perforated thereby in places.

Depending on the respective configuration of the structured surface 112 of the substrate 111, the conversion structure 125 can also have a shape and structure deviating from FIG. 21. By way of example, the elevations 113 and thus also the intermediate regions 127 of the conversion structure 125 can be positioned in a hexagonal arrangement. Furthermore, an irregular or random arrangement is possible.

Furthermore, the elevations 113 of the substrate 111 can be formed not only with a rectangular cross-sectional and plan view shape but also with other shapes and contours. By way of example, the elevations 113 can have a triangular or arched contour in cross section. As viewed from above, the elevations 113 can have a circular shape, for example. Moreover, the elevations 113 can be formed, if appropriate, non-uniformly with shapes deviating from one another. In the case of such configurations, the conversion structure 125 or the conversion regions 126 and the intermediate regions 127 present therebetween can have other shapes in the same way. Furthermore, a configuration can be appropriate in which, in a departure from FIG. 19, the elevations 113 and conversion regions 126 are not flush at the end side or do not form a planar end-side surface, rather for example the elevations 113 in part project beyond the conversion regions 126, or vice versa, or the conversion regions 126 are in part also arranged on the elevations 113. Such configurations can be present particularly in the case of elevations 113 having a cross-sectional shape deviating from a rectangular cross-sectional shape.

Like a subdivided conversion structure 120 described above, the continuous conversion structure 125 interrupted in places can comprise a suitable conversion material for radiation conversion. Possible examples are a ceramic conversion material or a semiconductor material, for example a II-VI compound semiconductor material. Production can be carried out in an analogous manner for example by the formation or application of a continuous layer of the conversion material to the substrate 111 and subsequent structuring, or with the aid of a lift-off process.

After the conversion structure 125 has been produced, as shown in FIG. 20 a semiconductor layer sequence 130 having an active zone 135 is formed on the side of the substrate 111 having the structured surface 112 and the conversion structure 125 (step 203). The formation of the semiconductor layer sequence 130, in the present case on the continuous conversion regions 126 and the elevations 113 arranged therebetween, is carried out with the aid of a deposition or epitaxy process as in the case of the embodiments described above. In this case, a suitable influencing of the layer growth can be brought about by the arrangement of conversion structure 125 and elevations 113. By way of example, growth present in the region of the conversion regions 126 can be slower than that in the region of the elevations 113. Consequently, the semiconductor layer sequence 130 or the seed layer thereof can be grown with an altered, in particular reduced, defect density.

For the case (not shown) where the conversion regions 126 project beyond the elevations 113, as indicated above, during the formation of the semiconductor layer sequence 130, semiconductor material is likewise introduced into the intermediate regions 127. In this case, the intermediate regions 127 can thus comprise different materials, i.e. besides the semiconductor material of the semiconductor layer sequence 130 material of the substrate 111 in the form of the elevations 113.

Afterward, further processes for completing a semiconductor chip emerging from the arrangement in FIG. 20 are carried out (step 204, not illustrated). In this case, above-described processes and also singulation can be carried out, and a semiconductor chip comparable to the semiconductor chip 100 in FIG. 3 can thus be produced. In this configuration, the conversion regions 126 of the conversion structure 125 are surrounded by the substrate 110 and the elevations 113 thereof and by the semiconductor layer sequence 130. If appropriate, it is also possible for the substrate 111 to be removed or a transfer process to be carried out in order to produce semiconductor chips comparable to the semiconductor chips 101, 102 in FIGS. 7, 8. In these embodiments, therefore, the conversion structure 125 is arranged in the region of a front or light exit side of the respective semiconductor chips. The removal of the substrate 111 can have the consequence that the front side is structured.

Besides the improved layer growth, the conversion structure 125 can afford the same advantages and effects as a subdivided conversion structure 120 described above. By way of example, it is possible to improve the extraction of light radiation from the semiconductor layer sequence 130, to reduce the reabsorption in the active zone 135, and to influence the emission profile. Equally, a small chip thickness and the generation of a white light radiation can be made possible. An effective cooling of the conversion regions 126 is furthermore advantageous. If appropriate, the combination of structured surface 112 and conversion structure 125 can bring about an intensification of one or more effects.

It is possible that further configurations that were mentioned above with regard to a subdivided conversion structure 120 can also be applied to the continuous conversion structure 125. By way of example, the conversion regions 126 of the conversion structure 125 can have not just an individual conversion material but a plurality of conversion materials, for example in the form of a material mixture, in order to generate different secondary radiations. It is also possible to form the conversion structure 125 in a manner comparable to the conversion structure 120 with multilayered conversion regions 126.

With regard to the conversion structure 125, furthermore, the possibility is also afforded of forming it on a substrate 110 having a smooth surface. Formation on a substrate 110 provided with an initial layer 139 is furthermore possible, such that the conversion structure 125 can be enclosed in a semiconductor layer sequence 130. In the case of such configurations in which the formation of semiconductor layers for forming the semiconductor layer sequence 130 leads to an arrangement of semiconductor material in the intermediate regions 127, the conversion structure 125 can likewise afford advantages such as an improved layer growth, for example.

Further possible configurations which may be appropriate for an optoelectronic semiconductor chip are described below. By way of example, for a subdivided conversion structure 120 which can be provided in accordance with FIGS. 3, 7, 8, 12, 13, 14 in the case of the semiconductor chips 100, 101, 102, 103, 104, 105 the configuration depicted in FIG. 22 can be employed instead of the configuration shown in FIG. 4.

FIG. 22 shows as an excerpt a schematic plan view illustration of a further conversion structure 120 comprising conversion regions 221 separated from one another. The conversion regions 221 are likewise designated hereinafter as structure elements 221. Like the structure elements 121 from FIG. 4, the structure elements 221 are separated from one another by intermediate regions 222 merging into one another. In contrast to the structure elements 121, the structure elements 221 have a circumferential closed shape. Each structure element 221 therefore encloses an inner region 223.

In the context of the production of a semiconductor chip comprising the conversion structure 120 shown in FIG. 22, which can be carried out as described above with a substrate 110, a substrate 110 coated with an initial layer 139, or a structured substrate 111, the structure elements 221 can be formed analogously to the structure elements 121 on the substrate 110, the initial layer 139 or on elevations 113 of the substrate 111 (step 202). In this case, the intermediate regions 222 and the inner regions 223 can firstly be present in the form of cutouts at which the substrate 110 or 111 or the initial layer 139 is exposed. The subsequent formation of a semiconductor layer sequence 130 or formation of further semiconductor layers for forming a semiconductor layer sequence 130 (step 203) has the consequence that semiconductor material of the semiconductor layer sequence 130 is arranged in the intermediate regions 222 and inner regions 223. In the case of the associated semiconductor chip produced, said regions 222, 223 therefore constitute non-converting regions.

The structure elements 221 can have a rectangular frame shape as viewed from above, as shown in FIG. 22. Alternatively, some other circumferential and closed shape, for example an annular shape, can be provided. Configurations are possible, moreover, in which structure elements 221 in each case enclose a plurality of inner regions 223. As viewed from the side, the structure elements 221 can have a rectangular cross-sectional shape, or alternatively some other contour, for example a triangular or curved contour. The structure elements 221 can furthermore be arranged in a regular rectangular spacing grid, as indicated in FIG. 22. A different arrangement, for example in a hexagonal grid, or else an irregular or random arrangement is also possible. Furthermore, the structure elements 221 can, if appropriate, be formed non-uniformly with shapes deviating from one another.

For the conversion structure 120 having the structure elements 221, further aspects that were mentioned with regard to the above-described conversion structure having the structure elements 121 can be employed in the same way. This concerns, for example, possible dimensions, production, which once again can be carried out from one or a plurality of conversion materials, a multilayered configuration, etc. Furthermore, with the conversion structure 120 comprising such structure elements 221, it is possible to obtain the same effects and advantages as were described above (for example improved layer growth, improvement in the extraction efficiency, reduction of a reabsorption, influencing of an emission profile, etc.).

An optoelectronic semiconductor chip can furthermore be formed on the basis of the abovementioned approaches with a plurality of conversion structures arranged in different planes. This can be carried out for example by modifying one of the above-described production methods in such a way that at least one further conversion structure is formed in the context of forming semiconductor layers for forming a semiconductor layer sequence 130.

In order to elucidate this aspect, FIG. 23 shows a lateral sectional view of a substrate 110 during the production of an optoelectronic semiconductor chip, wherein a conversion structure 120 and a semiconductor layer sequence 130 having an active zone 135 are arranged on a (smooth) side of the substrate. A further conversion structure 120 is arranged within the semiconductor layer sequence 130, said further conversion structure being arranged at a distance from the conversion structure 120 adjoining the substrate 110. The two conversion structures 120 can comprise for example the separate structure elements 121 shown in FIG. 4.

The construction shown in FIG. 23 can be produced in such a way that after steps 201 and 202 have been carried out for producing the arrangement shown in FIG. 1, in the context of step 203, i.e. forming the semiconductor layer sequence 130, the further conversion structure 120 is formed. In this case, the further conversion structure 120 is produced between the formation of successive semiconductor layers. The formation of the further conversion structure 120 on a semiconductor layer can be carried out, in a manner comparable to the formation—described with reference to FIG. 10—of a conversion structure 120 on the initial layer 139, by one of the methods described above. After the semiconductor layer sequence 130 has been formed, further processes for completing a semiconductor chip can be carried out in the manner described above (step 204). For details in this respect, reference is made to the above explanations.

The two conversion structures 120 comprising the structure elements 121 can be formed in accordance with the configurations described above. This concerns, for example, shapes, dimensions, arrangements, formation from one or a plurality of conversion materials, a multilayered configuration, etc. Furthermore, advantages demonstrated above can be present, if appropriate in intensified form on account of the two conversion structures 120.

It is possible for the conversion structures 120 present in different planes to be formed in a matching fashion, such that the structure elements 121 of the conversion structures 120 can have the same shape and comprise the same conversion material. As is indicated in FIG. 23, provision can furthermore be made, for example, for the structure elements 121 of the individual conversion structures 120 not to be positioned directly one above another, but rather in a manner offset with respect to one another. However, a direct arrangement one above another is also possible. It may furthermore be appropriate to form the conversion structures 120 in a manner deviating from one another. By way of example, different shapes of the structure elements 121 and/or the use of different conversion materials are/is possible, such that the different conversion structures 120 generate secondary light radiations in different spectral ranges.

Further modifications are possible with regard to the formation of a plurality of conversion structures. By way of example, more than two conversion structures 120 arranged in different planes can be formed. Furthermore, (at least) one conversion structure 120 or all the conversion structures 120 can comprise, instead of the structure elements 121, the structure elements 221 described with reference to FIG. 22. It is also possible to provide, instead of subdivided conversion structures 120, explicitly continuous conversion structures 125 (cf. FIG. 21) or else a combination of subdivided and continuous conversion structures 120, 125. In the case of such configurations, the conversion structures respectively provided can be formed in a matching fashion or in a manner deviating from one another (different shapes, materials, etc.).

Furthermore, it is also possible to provide a substrate coated with an initial layer 139 (cf. FIG. 9), such that a first conversion structure 120 or 125 is formed on the initial layer 139, and (at least) one further conversion structure 120 or 125 is subsequently formed in the context of forming further semiconductor layers for forming the semiconductor layer sequence 130. Furthermore, a structured substrate 111 can be employed instead of a smooth substrate 110. In this case, an arrangement as shown in FIG. 17 or FIG. 19 can be provided, and a semiconductor layer sequence 130 can subsequently be formed, wherein (at least) one further conversion structure 120 or 125 is formed in the context of forming the semiconductor layer sequence 130.

The embodiments explained with reference to the figures constitute preferred or exemplary embodiments of the invention. Further embodiments which can comprise further modifications or combinations of features are conceivable besides the embodiments described and depicted. By way of example, other materials can be used instead of the materials indicated above, and above indications concerning dimensions, numbers, etc. can be replaced by other indications. Moreover, it is possible to form semiconductor chips for generating light radiation of a different color, or abovementioned spectral ranges for primary and secondary radiations can be replaced by other spectral ranges. It is furthermore possible, in the case of the methods described, to carry out individual processes in a different order, if appropriate.

Instead of the embodiments of semiconductor chips shown in the figures, it is also possible to form differently constructed optoelectronic semiconductor chips, i.e. having other shapes and structures, in accordance with the above approaches, such that the semiconductor chips comprise (at least) one conversion structure 120, 125 for radiation conversion. Furthermore, semiconductor chips can comprise additional components and layers, for example connecting layers, buffer layers, passivation layers, etc.

A further possible modification consists in providing a substrate having a structured surface in the form of depressions present in the relevant side of the substrate. In this case, a conversion structure can be formed in a manner comparable to the conversion structure 120 in the form of separate conversion regions 121 which are arranged in the depressions or fill the depressions. Here, too, the depressions and thus the conversion regions 121 can be arranged for example in a regular grid. An irregular arrangement is also possible.

A further possible modification is the use of a structured substrate 111, on the structured surface 112 of which firstly an initial layer 139, subsequently a conversion structure 120 or 125, and afterward further layers of a semiconductor layer sequence 130 (and also, if appropriate, at least one further conversion structure) are formed.

Furthermore, attention is drawn to the possibility that, with the use of a coated substrate, an initial layer 139 situated on the substrate, on which initial layer a conversion structure can be formed (cf. FIG. 10), can be not just a seed layer or buffer layer of a semiconductor layer sequence 130. The initial layer 139 can also be a larger layer or a larger constituent of the semiconductor layer sequence 130 and therefore comprise at least one further partial layer of the semiconductor layer sequence 130 besides a seed or buffer layer.

Although the invention has been more specifically illustrated and described in detail by means of preferred or exemplary embodiments, nevertheless the invention is not restricted by the examples disclosed and other variations can be derived therefrom by the person skilled in the art, without departing from the scope of protection of the invention.

This patent applications claims the priority of German patent application 10 2013 200 509.1, the disclosure content of which is hereby incorporated by reference.

### LIST OF REFERENCE SIGNS

100, 101 Semiconductor chip
102, 103 Semiconductor chip
104, 105 Semiconductor chip
110, 111 Substrate
112 Structured surface
113 Elevation
115 Further substrate
120 Conversion structure
121 Conversion region, structure element
122 Intermediate region
123, 124 Layer
125 Conversion structure
126 Conversion region
127 Intermediate region
130 Semiconductor layer sequence
131, 132 Semiconductor layer
135 Active zone
139 Initial layer
141, 142 Contact
143 Layer
145 Intermediate layer
146 Metallic layer, contact
147 Contact
150 Through contact
151 Insulation layer
152 Conductive layer
155 Conductive layer
156 Metallic layer, contact
157 Contact
201, 202 Method step
203, 204 Method step
221 Conversion region, structure
element
222 Intermediate region
223 Inner region

1. An optoelectronic semiconductor chip, comprising:
a semiconductor layer sequence having an active zone for generating a light radiation;
a conversion structure, comprising conversion regions for converting the generated light radiation, non-converting regions being arranged between said conversion regions; and
a substrate having a structured surface, wherein
the conversion regions are arranged alongside one another in a plane parallel to the active zone of the semiconductor layer sequence,
the non-converting regions lie in the same plane between the conversion regions and are filled with a material of the semiconductor layer sequence and/or with a material of a substrate on which the semiconductor layer sequence is arranged,
the conversion structure is formed on the side of the substrate having the structured surface and the semiconductor layer sequence is formed on the side of the substrate with the conversion structure.

2. The optoelectronic semiconductor chip according to claim 1, wherein
the semiconductor layer sequence is based on a III-V compound semiconductor material,
the conversion regions are in direct contact with the semiconductor layer sequence,
the conversion regions comprise a first layer and a second layer, the first layer is based on a doped II-VI compound semiconductor material or III-V compound semiconductor material and is designed for converting the generated light radiation,
the first layer is encapsulated by the second layer to an extent such that there is no direct contact or there is a reduced contact between the first layer and the semiconductor layer sequence, and
the second layer comprises a metal nitride or a semiconductor nitride or a metal oxide or a semiconductor oxide and the constituents thereof at least partly differ from the constituents of the semiconductor layer sequence and of the first layer, wherein the second layer prevents direct growth of the semiconductor layer sequence on the conversion region.

3. The optoelectronic semiconductor chip according to claim 1, wherein the conversion regions are separated from one another.

4. The optoelectronic semiconductor chip according to claim 1, wherein the conversion regions form a continuous layer enclosing the non-converting regions.

5. The optoelectronic semiconductor chip according to claim 1, wherein the conversion structure is completely surrounded by the substrate and the semiconductor layer sequence.

6. (canceled)

7. The optoelectronic semiconductor chip according to claim 1,
wherein the conversion regions of the conversion structure are formed in a multilayered fashion.

8. (canceled)

9. The optoelectronic semiconductor chip according to claim 1, wherein the structured surface of the substrate has elevations, wherein the conversion regions are arranged between the elevations in such a way that a planar end side forms, wherein the semiconductor layer sequence is applied to said planar end side.

10. The optoelectronic semiconductor chip according to claim 1, comprising a plurality of conversion structures arranged in different planes.

11. The optoelectronic semiconductor chip according to claim 1, comprising a plurality of separate conversion regions which are separated from one another and which are enclosed within the semiconductor layer sequence, such that the semiconductor layer sequence completely surrounds the conversion regions all around, wherein at least two of the conversion regions are arranged alongside one another in a plane parallel to the active zone.

12. A method for producing an optoelectronic semiconductor chip, comprising the following method steps:
providing a substrate with a structured surface;
forming a conversion structure on the structured surface of the substrate, wherein the conversion structure comprises conversion regions for converting a light radiation, non-converting regions being provided between said conversion regions; and
forming semiconductor layers on the substrate and on the conversion regions of the conversion structure, wherein a semiconductor layer sequence having an active zone for generating a light radiation is formed, which light radiation is convertible with the aid of the conversion regions of the conversion structure, wherein
the conversion regions are arranged alongside one another in a plane parallel to the active zone of the semiconductor layer sequence, and
the non-converting regions lie in the same plane between the conversion regions and are filled with a material of the semiconductor layer sequence and/or with a material of a substrate on which the semiconductor layer sequence is arranged.

13. The method according to claim 12,
wherein the conversion structure is formed in such a way that the conversion regions are separated from one another.

14. The method according to claim 12,
wherein the conversion structure is formed in such a way that the conversion regions form a continuous layer enclosing the non-converting regions.

15. The method according to claim 12,
wherein the substrate is provided having an initial layer at one side, and wherein the conversion structure and the semiconductor layers are formed on the initial layer of the substrate.

16. The method according to claim 12, further comprising removing the substrate used for forming the semiconductor layer sequence.

17. The method according to claim 12, wherein the conversion regions of the conversion structure are formed in a multilayered fashion.

18. (canceled)

19. The method according to claim 12, wherein at least one further conversion structure is formed in the context of forming semiconductor layers for forming the semiconductor layer sequence.

20. An optoelectronic semiconductor chip, comprising:
a semiconductor layer sequence having an active zone for generating a light radiation; and
a conversion structure, comprising conversion regions for converting the generated light radiation, non-converting regions being arranged between said conversion regions.

21. The optoelectronic semiconductor chip according to claim 20, further comprising a substrate, wherein the conversion structure is arranged in the region of a side of the semiconductor layer sequence facing away from the substrate.
